(19) United States
(12) Patent Application Publication
(10) Pub. No.: US 2024/0321895 A1
(43) Pub. Date: Sep. 26, 2024

(54) DISPLAY DEVICE AND METHOD OF MANUFACTURING THE SAME

(71) Applicant: Samsung Display Co., Ltd., Yongin-Si (KR)

(72) Inventors: Yeonhong Kim, Yongin-si (KR); Jongbeom Ko, Yongin-si (KR); Eunhyun Kim, Yongin-si (KR); Junghoon Lee, Yongin-si (KR); Sunhee Lee, Yongin-si (KR)

(21) Appl. No.: 18/528,823

(22) Filed: Dec. 5, 2023

(30) Foreign Application Priority Data
Mar. 24, 2023 (KR) 10-2023-0039257
May 2, 2023 (KR) 10-2023-0057348

(51) Int. Cl. H01L 27/12

(52) U.S. Cl. CPC H01L 27/1218; H01L 27/1237; H10K 59/1201; H10K 59/1213; H10K 2102/351

(57) ABSTRACT

A display device includes a substrate, a first oxide semiconductor layer on the substrate, a first gate insulating layer on the substrate and covering an upper surface of the first oxide semiconductor layer, a second oxide semiconductor layer on the first gate insulating layer, and a second gate insulating layer covering an upper surface of the second oxide semiconductor layer. The first oxide semiconductor layer includes a channel region between a source region and a drain region The second oxide semiconductor layer includes a channel region between a source region and a drain region. A difference between a thickness of the first gate insulating layer and a thickness of the second gate insulating layer is 500 Å or less.

### CROSS-REFERENCE TO RELATED APPLICATION

This application is based on and claims priority under 35 U.S.C. § 119 to Korean Patent Application Nos. 10-2023-0039257, filed on Mar. 24, 2023, and 10-2023-0057348, filed on May 2, 2023, in the Korean Intellectual Property Office, the disclosures of which are incorporated by reference herein in their entireties.

### BACKGROUND

### 1. Field

One or more embodiments relate to a display device and a method of manufacturing the same.

### 2. Description of the Related Art

Mobile electronic devices are widely used. As mobile electronic devices, tablet personal computers have been widely used in recent years in addition to small electronic devices such as mobile phones.

Such mobile electronic devices include display devices to support various functions, for example, to provide visual information, such as images or videos, to users. Recently, as other parts for driving display devices have been miniaturized, the proportion occupied by display devices in electronic devices has gradually increased. Structures capable of being bent from a flat state to have a certain angle are also under development.

### SUMMARY

One or more embodiments include a display device and a method of manufacturing the same.

Additional aspects will be set forth in part in the description which follows and, in part, will be apparent from the description, or may be learned by practice of the presented embodiments of the disclosure.

According to one or more embodiments, a display device includes a substrate, a first oxide semiconductor layer disposed on the substrate, the first oxide semiconductor layer including a channel region, a source region, and a drain region, the source region and the drain region being spaced apart from each other with the channel region therebetween, a first gate insulating layer continuously disposed on the substrate and covering an upper surface of the first oxide semiconductor layer, a second oxide semiconductor layer disposed on the first gate insulating layer, the second oxide semiconductor layer including a channel region, a source region, and a drain region, the source region and the drain region being spaced apart from each other with the channel region therebetween, and a second gate insulating layer disposed to cover an upper surface of the second oxide semiconductor layer, wherein the first gate insulating layer has a first thickness in a direction perpendicular to the substrate, the second gate insulating layer has a second thickness in a direction perpendicular to the substrate, and a difference between the first thickness and the second thickness is 500 Å or less.

According to the present embodiment, the first gate insulating layer may be disposed to completely cover the upper surface of the first oxide semiconductor layer, and the second gate insulating layer may be disposed to completely cover the upper surface of the second oxide semiconductor layer.

According to the present embodiment, the first gate insulating layer and the second gate insulating layer may include a same material as each other.

According to the present embodiment, the display device may further include a third oxide semiconductor layer disposed on the substrate.

According to the present embodiment, the first oxide semiconductor layer and the second oxide semiconductor layer may include different materials from each other.

According to the present embodiment, the first oxide semiconductor layer may include indium gallium zinc oxide (IGZO), and the second oxide semiconductor layer may include indium tin gallium zinc oxide (ITGZO).

According to the present embodiment, the first oxide semiconductor layer may include ITGZO, and the second oxide semiconductor layer may include IGZO.

According to the present embodiment, the third oxide semiconductor layer may include IGZO and/or ITGZO.

According to the present embodiment, the first oxide semiconductor layer or the second oxide semiconductor layer may have a structure in which a layer including IGZO and a layer including ITGZO are stacked in multiple layers.

According to the present embodiment, the source region and the drain region of the first oxide semiconductor layer and the source region and the drain region of the second oxide semiconductor layer may include doped ions.

According to the present embodiment, the display device may further include a first gate electrode disposed on the first gate insulating layer and overlapping the channel region of the first oxide semiconductor layer, and a second gate electrode disposed on the second gate insulating layer and overlapping the channel region of the second oxide semiconductor layer.

According to one or more embodiments, a method of manufacturing a display device includes forming a first oxide semiconductor layer and a third oxide semiconductor layer on a substrate, forming a first gate insulating layer on the first oxide semiconductor layer and the third oxide semiconductor layer, the first gate insulating layer being continuously formed on the substrate to completely cover upper surfaces of the first oxide semiconductor layer and the third oxide semiconductor layer, forming a second oxide semiconductor layer on the first gate insulating layer, and forming a second gate insulating layer on the second oxide semiconductor layer to completely cover an upper surface of the second oxide semiconductor layer, wherein the first gate insulating layer has a first thickness in a direction perpendicular to the substrate, the second gate insulating layer has a second thickness in a direction perpendicular to the substrate, and a difference between the first thickness and the second thickness is 500 Å or less.

According to the present embodiment, the forming of the second gate insulating layer on the second oxide semiconductor layer to completely cover the upper surface of the second oxide semiconductor layer may include disposing a second gate insulating layer forming material on the second oxide semiconductor layer, disposing a photoresist on a portion of the second gate insulating layer forming material overlapping the second oxide semiconductor layer, forming a second gate insulating layer by etching a portion of the second gate insulating layer forming material on which the photoresist is not disposed, and removing the photoresist.

According to the present embodiment, the method may further include forming, on the first gate insulating layer, a first gate electrode overlapping at least a portion of the first oxide semiconductor layer, and forming, on the second gate insulating layer, a second gate electrode overlapping at least a portion of the second oxide semiconductor layer.

According to the present embodiment, the method may further include doping ion impurities into a portion of the first oxide semiconductor layer that does not overlap the first gate electrode, a portion of the second oxide semiconductor layer that does not overlap the second gate electrode, and the third oxide semiconductor layer.

According to the present embodiment, the first oxide semiconductor layer and the second oxide semiconductor layer may include different materials from each other.

According to the present embodiment, the first oxide semiconductor layer may include indium gallium zinc oxide (IGZO), and the second oxide semiconductor layer may include indium tin gallium zinc oxide (ITGZO).

According to the present embodiment, the first oxide semiconductor layer may include ITGZO, and the second oxide semiconductor layer may include IGZO.

According to the present embodiment, the first oxide semiconductor layer or the second oxide semiconductor layer may have a structure in which a layer including IGZO and a layer including ITGZO are stacked in multiple layers.

According to one or more embodiments, a display device includes a substrate, a first oxide semiconductor layer disposed on the substrate, the first oxide semiconductor layer including a channel region, a source region, and a drain region, the source region and the drain region being spaced apart from each other with the channel region therebetween, a first gate insulating layer continuously disposed on the substrate and completely covering an upper surface of the first oxide semiconductor layer, a second oxide semiconductor layer disposed on the first gate insulating layer, the second oxide semiconductor layer including a channel region, a source region, and a drain region, the source region and the drain region being spaced apart from each other with the channel region therebetween, and a second gate insulating layer continuously disposed on the substrate and completely covering an upper surface of the second oxide semiconductor layer, wherein the source region and the drain region of the first oxide semiconductor layer and the source region and the drain region of the second oxide semiconductor layer include doped ions.

According to the present embodiment, the display device may further include a third oxide semiconductor layer disposed on the substrate.

According to one or more embodiments, a method of manufacturing a display device includes forming a first oxide semiconductor layer and a third oxide semiconductor layer on a substrate, forming a first gate insulating layer on the first oxide semiconductor layer and the third oxide semiconductor layer, the first gate insulating layer being continuously formed on the substrate to completely cover upper surfaces of the first oxide semiconductor layer and the third oxide semiconductor layer, forming a second oxide semiconductor layer on the first gate insulating layer, and forming a second gate insulating layer on the second oxide semiconductor layer, the second gate insulating layer being continuously formed on the substrate to completely cover an upper surface of the second oxide semiconductor layer, wherein at least a portion of the first oxide semiconductor layer and at least a portion of the second oxide semiconductor layer include doped ions.

According to the present embodiment, the method may further include, after the forming of the first gate insulating layer on the first oxide semiconductor layer and the third oxide semiconductor layer, the first gate insulating layer being continuously formed on the substrate to completely cover the upper surfaces of the first oxide semiconductor layer and the third oxide semiconductor layer, forming, on the first gate insulating layer, a photoresist overlapping at least a portion of the first oxide semiconductor layer, doping ions into the third oxide semiconductor layer and a portion of the first oxide semiconductor layer that does not overlap the photoresist, and removing the photoresist.

According to the present embodiment, the method may further include, after the forming of the second gate insulating layer on the second oxide semiconductor layer, the second gate insulating layer being continuously formed on the substrate to completely cover the upper surface of the second oxide semiconductor layer, forming a photoresist to overlap entirety of the first oxide semiconductor layer, entirety of the third oxide semiconductor layer, and at least a portion of the second oxide semiconductor layer, doping ions into a portion of the second oxide semiconductor layer that does not overlap the photoresist, and removing the photoresist.

### BRIEF DESCRIPTION OF THE DRAWINGS

The above and other aspects, features, and advantages of certain embodiments of the disclosure will be more apparent from the following description taken in conjunction with the accompanying drawings.

FIGS. 1A and 1B are perspective views schematically illustrating a display device according to an embodiment.

FIGS. 2A and 2B are equivalent circuit diagrams schematically illustrating a light-emitting diode corresponding to a sub-pixel of a display device, and a sub-pixel circuit electrically connected to the light-emitting diode, according to an embodiment.

FIGS. 3A and 3B are cross-sectional views schematically illustrating a display device according to an embodiment.

FIGS. 4, 5, 6, 7, 8, 9, 10, 11, 12, and 13 are cross-sectional views schematically illustrating a method of manufacturing a display device, according to an embodiment.

FIG. 14 is a cross-sectional view schematically illustrating a display device according to an embodiment.

FIGS. 15, 16, 17, 18, 19, 20, and 21 are cross-sectional views schematically illustrating a method of manufacturing a display device, according to an embodiment.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, only certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements in different figures may be denoted by the same reference numerals. Also, sizes of elements in the drawings may be exaggerated or reduced for convenience of explanation. For example, because sizes and thicknesses of elements in the drawings are arbitrarily illustrated for convenience of explanation, the disclosure is not limited thereto.

It will be understood that although the terms “first,” “second,” etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

It will be further understood that when layers, regions, or elements are referred to as being connected to each other, they may be directly connected to each other or indirectly connected to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

When a certain embodiment may be implemented differently, a specific process order may be performed differently from the described order. For example, two consecutively described processes may be performed substantially at the same time or performed in an order opposite to the described order.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

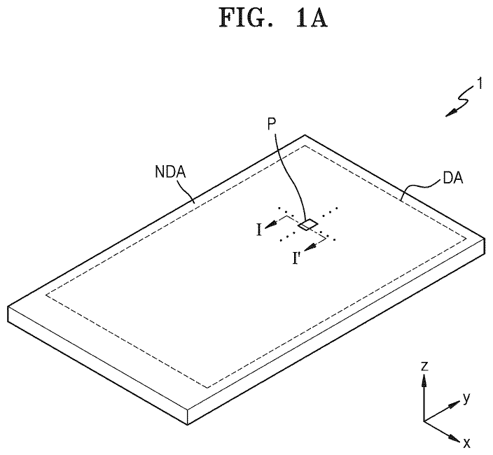

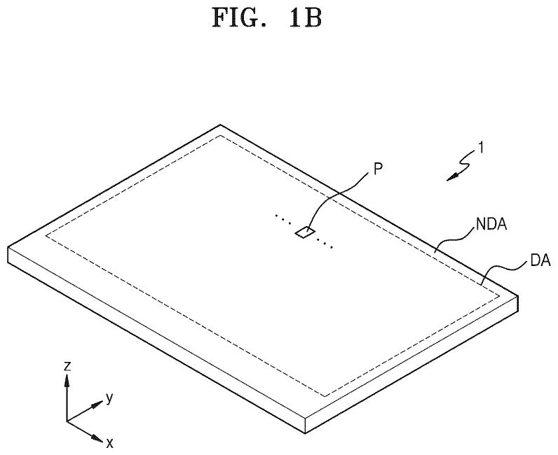

FIGS. 1A and 1B are perspective views schematically illustrating a display device 1 according to an embodiment.

Referring to FIGS. 1A and 1B, the display device 1 may include a display area DA and a non-display area NDA outside the display area DA. The display area DA is an area that displays an image using sub-pixels P arranged therein. The non-display area NDA is an area that is outside the display area DA, does not display an image, and may completely surround the display area DA. A driver or the like that provides electrical signals or power to the display area DA may be in the non-display area NDA. A pad, which is an area to which an electronic element or a printed circuit board may be electrically connected, may be arranged in the non-display area NDA.

In an embodiment, FIG. 1A illustrates that the display device 1 has a polygonal shape (e.g., a rectangular shape) in which the length of the display area DA in the x direction is less than the length of the display area DA in the y direction, but in another embodiment, FIG. 1B illustrates that the display device 1 may have a polygonal shape (e.g., a rectangular shape) in which the length of the display area DA in the y direction is less than the length of the display area DA in the x direction. Although FIGS. 1A and 1B illustrate that the display area DA has a substantially rectangular shape, the disclosure is not limited thereto. In another embodiment, the display area DA may have various shapes, such as an N-gonal shape (where N is a natural number greater than or equal to 3), a circular shape, or an elliptical shape. FIGS. 1A and 1B illustrate that the corners of the display area DA have a shape including vertices at which straight lines cross each other, but in another embodiment, the corners of the display area DA may have a round polygonal shape.

Hereinafter, for convenience of description, a case where the display device 1 is an electronic device such as a smartphone is described, but the display device 1 according to the disclosure is not limited thereto. The display device 1 may be used in portable electronic devices, such as mobile phones, smartphones, tablet personal computers, mobile communication terminals, electronic organizers, e-books, portable multimedia players (PMPs), navigation systems, and ultra mobile personal computers (UMPCs). Also, the display device 1 may be used in various products, such as televisions, laptops, monitors, billboards, and Internet of things (IoT) devices. The display device 1 according to an embodiment may also be applied to wearable devices, such as smart watches, watch phones, glasses-type displays, and head mounted displays (HMDs). The display device 1 according to an embodiment may also be used in dashboards of automobiles, center information displays (CIDs) on the center fascia or dashboards of automobiles, room mirror displays replacing side mirrors of automobiles, and display screens on the rear sides of front seats to serve as entertainment devices for backseat passengers of automobiles.

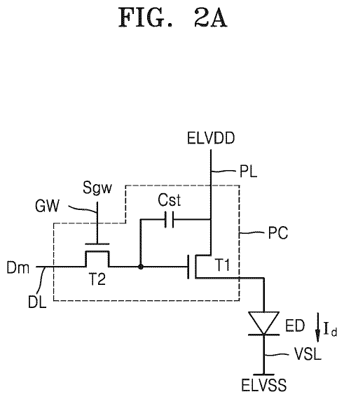

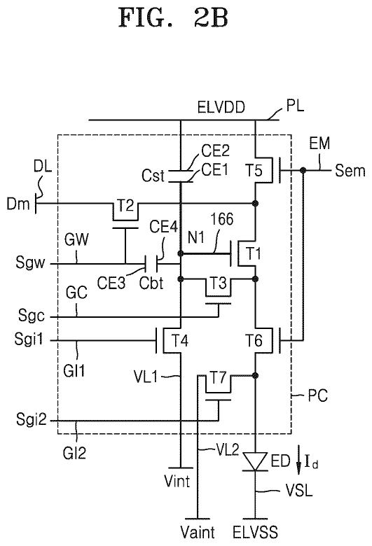

FIGS. 2A and 2B are equivalent circuit diagrams schematically illustrating an embodiment of a sub-pixel of a display device, the sub-pixel including a light-emitting diode ED and a sub-pixel circuit PC electrically connected to the light-emitting diode ED.

Referring to FIG. 2A, the light-emitting diode ED may be electrically connected to the sub-pixel circuit PC, and the sub-pixel circuit PC may include a first transistor T1, a second transistor T2, and a storage capacitor Cst. A sub-pixel electrode (e.g., an anode) of the light-emitting diode ED may be electrically connected to the first transistor T1, and an opposite electrode (e.g., a cathode) of the light-emitting diode ED may be electrically connected to an auxiliary line VSL and configured to receive a voltage corresponding to a common voltage ELVSS through the auxiliary line VSL.

The second transistor T2 may be configured to transmit a data signal Dm from a data line DL to a gate of the first transistor T1 in response to a scan signal Sgw input to the transistor T2 through a scan line GW.

The storage capacitor Cst may be connected to the second transistor T2 and a driving voltage line PL and may be configured to store a voltage corresponding to a difference between a voltage received from the second transistor T2 and a driving voltage ELVDD supplied to the driving voltage line PL.

The first transistor T1 may be connected to the driving voltage line PL and the storage capacitor Cst and may be configured to control a driving current I_{d} flowing from the driving voltage line PL to the light-emitting diode ED according to a voltage value stored in the storage capacitor Cst. The light-emitting diode ED may be configured to emit light having a certain luminance according to the driving current I_{d}.

FIG. 2A illustrates that the sub-pixel circuit PC includes two transistors and one storage capacitor, but the disclosure is not limited thereto.

Referring to FIG. 2B, the sub-pixel circuit PC may include seven transistors and two capacitors.

The sub-pixel circuit PC in FIG. 2 may include first to seventh transistors T1, T2, T3, T4, T5, T6, and T7, a storage capacitor Cst, and a boost capacitor Cbt. In another embodiment, the sub-pixel circuit PC may not include the boost capacitor Cbt. A sub-pixel electrode (e.g., an anode) of the light-emitting diode ED may be electrically connected to the first transistor T1 via the sixth transistor T6, and an opposite electrode (e.g., a cathode) of the light-emitting diode ED may be electrically connected to an auxiliary line VSL and configured to receive a voltage corresponding to a common voltage ELVSS through the auxiliary line VSL.

In an embodiment, the first to seventh transistors T1, T2, T3, T4, T5, T6, and T7 may each be an n-channel metal-oxide semiconductor field effect transistor (MOSFET) or a N-type metal-oxide-semiconductor (NMOS) device. For example, the first to seventh transistors T1, T2, T3, T4, T5, T6, and T7 may each be an NMOS including an oxide-based semiconductor material. However, the disclosure is not limited thereto.

The first to seventh transistors T1, T2, T3, T4, T5, T6, and T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and a data line DL. The sub-pixel circuit PC may be electrically connected to voltage lines, for example, a driving voltage line PL, a first initialization voltage line VL1, and a second initialization voltage line VL2.

The first transistor T1 may be a driving transistor. A gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a first electrode (e.g., an anode) of the light-emitting diode ED via the sixth transistor T6. One of the first electrode and the second electrode of the first transistor T1 may be a source electrode and the other thereof may be a drain electrode. The first transistor T1 may be configured to supply a driving current I_{d} to the light-emitting diode ED according to the switching operation of the second transistor T2.

The second transistor T2 may be a switching transistor. A gate electrode of the second transistor T2 may be connected to the scan line GW, a first electrode of the second transistor T2 may be connected to the data line DL, and a second electrode of the second transistor T2 may be connected to the first electrode of the first transistor T1 and electrically connected to the driving voltage line PL via the fifth transistor T5. One of the first electrode and the second electrode of the second transistor T2 may be a source electrode and the other thereof may be a drain electrode. The second transistor T2 may be configured to be turned on in response to a scan signal Sgw received through the scan line GW and to perform a switching operation of transmitting, to the first electrode of the first transistor T1, a data signal Dm received through the data line DL.

The third transistor T3 may be a compensation transistor configured to compensate for a threshold voltage of the first transistor T1. A gate electrode of the third transistor T3 may be connected to the compensation gate line GC. A first electrode of the third transistor T3 may be connected to a lower electrode CE1 of the storage capacitor Cst and to the gate electrode of the first transistor T1 through a node connection line 166. The first electrode of the third transistor T3 may be connected to the fourth transistor T4. A second electrode of the third transistor T3 may be connected to the second electrode of the first transistor T1 and electrically connected to the first electrode (e.g., the anode) of the light-emitting diode ED via the sixth transistor T6. One of the first electrode and the second electrode of the third transistor T3 may be a source electrode and the other thereof may be a drain electrode.

The third transistor T3 may be configured to be turned on in response to a compensation signal Sgc received through the compensation gate line GC and may electrically connect the gate electrode of the first transistor T1 to the second electrode (e.g., the drain electrode) of the first transistor T1. Therefore, the first transistor T1 may be diode-connected when the compensation signal Sgc turns on the third transistor T3.

The fourth transistor T4 may be a first initialization transistor configured to initialize the gate electrode of the first transistor T1. A gate electrode of the fourth transistor T4 may be connected to the first initialization gate line GI1. A first electrode of the fourth transistor T4 may be connected to the first initialization voltage line VL1. The second electrode of the fourth transistor T4 may be connected to the lower electrode CE1 of the storage capacitor Cst, the first electrode of the third transistor T3, and the gate electrode of the first transistor T1. One of the first electrode and the second electrode of the fourth transistor T4 may be a source electrode and the other thereof may be a drain electrode. The fourth transistor T4 may be configured to be turned on in response to the first initialization signal Sgi1 received through the first initialization gate line GI1 and may perform an initialization operation of initializing the voltage of the gate electrode of the first transistor T1 by transmitting a first initialization voltage Vint to the gate electrode of the first transistor T1.

The fifth transistor T5 may be an operation control transistor. A gate electrode of the fifth transistor T5 may be connected to the emission control line EM, a first electrode of the fifth transistor T5 may be connected to the driving voltage line PL, and a second electrode of the fifth transistor T5 may be connected to the first electrode of the first transistor T1 and the second electrode of the second transistor T2. One of the first electrode and the second electrode of the fifth transistor T5 may be a source electrode and the other thereof may be a drain electrode.

The sixth transistor T6 may be an emission control transistor. A gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the first electrode (e.g., the anode) of the light-emitting diode ED. One of the first electrode and the second electrode of the sixth transistor T6 may be a source electrode and the other thereof may be a drain electrode.

The fifth transistor T5 and the sixth transistor T6 may be configured to be simultaneously turned on in response to the emission control signal Sem received through the emission control line EM and transmit the driving voltage ELVDD to the light-emitting diode ED so that the driving current I_{d} flows through the light emitting diode ED.

The seventh transistor T7 may be a second initialization transistor configured to initialize the first electrode (e.g., the anode) of the light-emitting diode ED. A gate electrode of the seventh transistor T7 may be connected to the second initialization gate line GI2. A first electrode of the seventh transistor T7 may be connected to the second initialization voltage line VL2. The second electrode of the seventh transistor T7 may be connected to the second electrode of the sixth transistor T6 and the first electrode (e.g., the anode) of the light-emitting diode ED. The seventh transistor T7 may be configured to be turned on in response to a second initialization signal Sgi2 received through the second initialization gate line GI2 and initialize the first electrode of the light-emitting diode ED by transmitting a second initialization voltage Vaint to the first electrode (e.g., the anode) of the light-emitting diode ED.

In some embodiments, the second initialization voltage line VL2 may be a next scan line. For example, the second initialization gate line GI2 connected to the seventh transistor T7 of the sub-pixel circuit PC in the i^{th} row (where i is a natural number) may correspond to the scan line of the sub-pixel circuit PC in the (i+1)th row. In another embodiment, the second initialization voltage line VL2 may be the emission control line EM. For example, the emission control line EM may be electrically connected to the fifth to seventh transistors T5, T6, and T7.

The storage capacitor Cst may include the lower electrode CE1 and an upper electrode CE2. The lower electrode CE1 of the storage capacitor Cst may be connected to the gate electrode of the first transistor T1, and the upper electrode CE2 of the storage capacitor Cst may be connected to the driving voltage line PL. The storage capacitor Cst may be configured to store electric charges corresponding to a difference between the voltage of the gate electrode of the first transistor T1 and the driving voltage ELVDD.

The boost capacitor Cbt may include a third electrode CE3 and a fourth electrode CE4. The third electrode CE3 may be connected to the gate electrode of the second transistor T2 and the scan line GW, and the fourth electrode CE4 may be connected to the first electrode of the third transistor T3 and the node connection line 166. When the scan signal Sgw supplied to the scan line GW is turned off, the boost capacitor Cbt may increase a voltage of a first node N1. When the voltage of the first node N1 is increased, a black gray scale may be clearly expressed.

The first node N1 may be an area in which the gate electrode of the first transistor T1, the first electrode of the third transistor T3, the second electrode of the fourth transistor T4, and the fourth electrode CE4 of the boost capacitor Cbt are connected to each other.

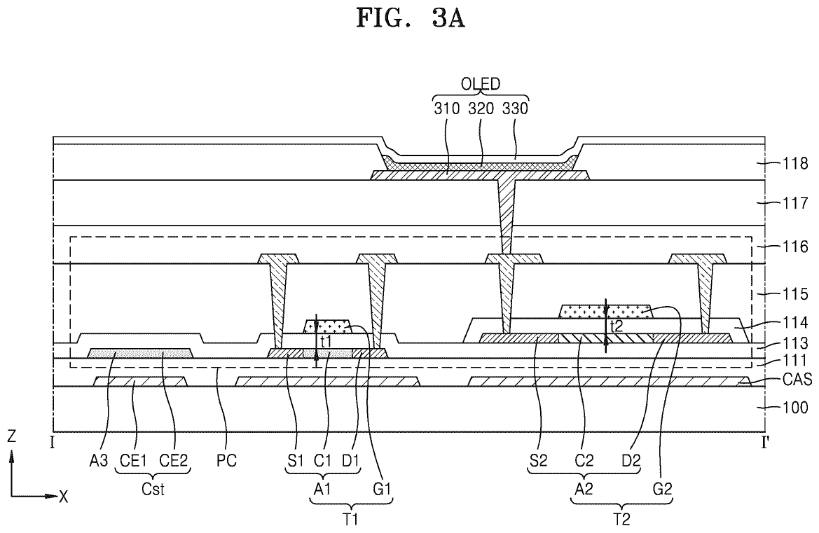

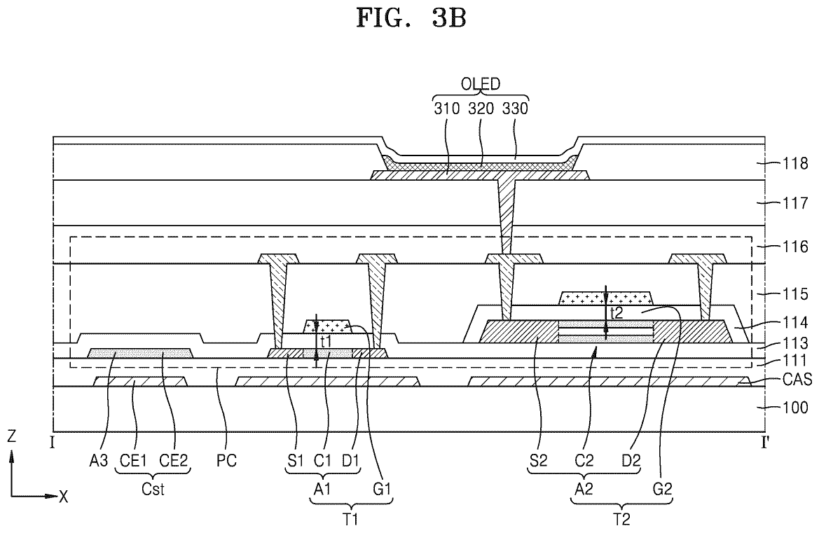

FIGS. 3A and 3B are cross-sectional views schematically illustrating a display device according to an embodiment. Specifically, FIGS. 3A and 3B are schematic cross-sectional views of embodiments of one of the sub-pixels P in the display device 1 of FIG. 1A taken along line I-I′ of FIG. 1A.

Referring to FIGS. 3A and 3B, a substrate 100 may include a glass material or a polymer resin. Although not illustrated, the substrate 100 may include a structure in which an inorganic barrier layer and a base layer including polymer resin are stacked. Examples of the polymer resin may polyethersulfone (PES), polyarylate (PAR), polyetherimide (PEI), polyethylene naphthalate (PEN), polyethylene terephthalate (PET), polyphenylene sulfide (PPS), polyarylate, polyimide (PI), polycarbonate, cellulose triacetate (TAC), or cellulose acetate propionate (CAP).

A bottom metal layer CAS may be disposed on the substrate 100 and may act as a charge annihilation shield. The bottom metal layer CAS may be formed or patterned to include regions that overlap a first oxide semiconductor layer A1, a second oxide semiconductor layer A2, and a third oxide semiconductor layer A3. A voltage may be applied to the bottom metal layer CAS. For example, the bottom metal layer CAS may form a storage capacitor Cst together with the third oxide semiconductor layer A3. Specifically, the bottom metal layer CAS may function as the lower electrode CE1 of the storage capacitor Cst, and the third oxide semiconductor layer A3 may function as the upper electrode CE2 of the storage capacitor Cst. In addition, the bottom metal layer CAS may prevent external light from reaching the first oxide semiconductor layer A1, the second oxide semiconductor layer A2, and the third oxide semiconductor layer A3. Accordingly, characteristics of the first transistor T1 formed using the first oxide semiconductor layer A1 or the second transistor T2 formed using the second oxide semiconductor layer A2 may be stabilized. On the other hand, in some cases, the bottom metal layer CAS may be omitted.

A buffer layer 111 may be disposed on the bottom metal layer CAS. The buffer layer 111 may be continuously disposed on the substrate 100. The buffer layer 111 may prevent infiltration of impurities into the oxide semiconductor layers of the transistors. The buffer layer 111 may include an inorganic insulating material, such as silicon nitride, silicon oxynitride, and silicon oxide, and may include a single layer or multiple layers including any of the inorganic insulating materials described above.

The sub-pixel circuit PC may be disposed on the buffer layer 111. The sub-pixel circuit PC may include the first transistor T1, the second transistor T2, and the storage capacitor Cst. However, the disclosure is not limited thereto.

The first transistor T1 may include the first oxide semiconductor layer A1 on the substrate 100 and a first gate electrode G1 overlapping a channel region C1 of the first oxide semiconductor layer A1. The first oxide semiconductor layer A1 may be disposed on the buffer layer 111.

The first oxide semiconductor layer A1 may include indium gallium zinc oxide (IGZO) or indium tin gallium zinc oxide (ITGZO). When the first oxide semiconductor layer A1 of the first transistor T1 includes ITGZO that is a high electron mobility material, the first transistor T1 may function as a switching transistor. Alternatively, when the first oxide semiconductor layer A1 of the first transistor T1 includes IGZO that is a low electron mobility material, the first transistor T1 may function as a driving transistor.

The first oxide semiconductor layer A1 may include the channel region C1, a source region S1, and a drain region D1, the source region S1 and the drain region D1 being spaced apart from each other with the channel region C1 therebetween. The source region S1 of the first oxide semiconductor layer A1 may be connected to a source electrode disposed on a third insulating layer 115, and the drain region D1 of the first oxide semiconductor layer A1 may be connected to a drain electrode disposed on the third insulating layer 115. The source region S1 and the drain region D1 of the first oxide semiconductor layer A1 may include impurities at a higher concentration than is in the channel region C1. Specifically, the source region S1 and the drain region D1 of the first oxide semiconductor layer A1 may include doped ions. The source region S1 and the drain region D1 of the first oxide semiconductor layer A1 may include boron or fluorine as a dopant.

The first gate electrode G1 may be disposed on a first gate insulating layer 113 and overlap the channel region C1 of the first oxide semiconductor layer A1. The first gate electrode G1 may include a conductive material including molybdenum (Mo), aluminum (Al), copper (Cu), titanium (Ti), and the like, and may include a single layer or multiple layers including any of the conductive materials described above.

The second transistor T2 may include a second oxide semiconductor layer A2 and a second gate electrode G2 overlapping a channel region C2 of the second oxide semiconductor layer A2. Specifically, the second oxide semiconductor layer A2 may be disposed on the first gate insulating layer 113. The second oxide semiconductor layer A2 may be between the first gate insulating layer 113 and a second gate insulating layer 114.

The second oxide semiconductor layer A2 may include a material that is different from the material in the first oxide semiconductor layer A1. When the first oxide semiconductor layer A1 includes IGZO, the second oxide semiconductor layer A2 may include ITGZO that is different from the IGZO in the first oxide semiconductor layer A1. When the second oxide semiconductor layer A2 includes ITGZO that is a high electron mobility material, the second transistor T2 may function as a switching transistor. In addition, when the first oxide semiconductor layer A1 includes ITGZO, the second oxide semiconductor layer A2 may include IGZO that is different from the material in the first oxide semiconductor layer A1. When the second oxide semiconductor layer A2 includes IGZO that is a low electron mobility material, the second transistor T2 may function as a driving transistor.

As illustrated in FIG. 3B, the second oxide semiconductor layer A2 may have a stack structure including multiple layers of different materials. Specifically, the second oxide semiconductor layer A2 may include a first layer, a second layer, and a third layer. The second layer may be in contact with the upper surface of the first layer, and the third layer may be in contact with the upper surface of the second layer. The first layer and the third layer may each include IGZO, and the second layer may include ITGZO. However, the disclosure is not limited thereto. The second oxide semiconductor layer A2 may have a stack structure of five layers instead of three layers. The first layer and the third layer may each include ITGZO, and the second layer may include IGZO. In addition, the first oxide semiconductor layer A1 may also have a structure in which a layer including ITGZO and a layer including ITGZO are stacked in multiple layers.

The second oxide semiconductor layer A2 may include the channel region C2, a source region S2, and a drain region D2, the source region S2 and the drain region D2 being spaced apart from each other with the channel region C2 therebetween. The source region S2 of the second oxide semiconductor layer A2 may be connected to a source electrode disposed on the third insulating layer 115, and the drain region D2 of the second oxide semiconductor layer A2 may be connected to a drain electrode disposed on the third insulating layer 115. The source region S2 and the drain region D2 of the second oxide semiconductor layer A2 may include impurities at a higher concentration than is in the channel region C2. Specifically, the source region S2 and the drain region D2 of the second oxide semiconductor layer A2 may include doped ions. The source region S2 and the drain region D2 of the second oxide semiconductor layer A2 may include boron or fluorine as a dopant.

The second gate electrode G2 may be disposed on the second gate insulating layer 114 and may overlap the channel region C2 of the second oxide semiconductor layer A2. The second gate electrode G2 may include a conductive material such as molybdenum (Mo), aluminum (Al), copper (Cu), titanium (Ti), and the like and may include a single layer or multiple layers including any of the conductive materials described above.

The first gate insulating layer 113 may be disposed on the first oxide semiconductor layer A1. The first gate insulating layer 113 may be continuously disposed on the substrate 100 and cover the upper surface of the first oxide semiconductor layer A1. The first gate insulating layer 113 may be continuously disposed on the substrate 100 and completely cover the upper surface of the first oxide semiconductor layer A1. The first gate insulating layer 113 may include silicon oxide (SiOx). The first gate insulating layer 113 in contact with the upper surface of the first oxide semiconductor layer A1 may have a first thickness t1 in a direction perpendicular to the substrate 100.

The second gate insulating layer 114 may be disposed on the second oxide semiconductor layer A2. The second gate insulating layer 114 may be disposed to completely cover the upper surface of the second oxide semiconductor layer A2. In an embodiment, the second gate insulating layer 114 may not be continuously formed on the substrate 100 but may be disposed to cover only the upper surface or side surface of the second oxide semiconductor layer A2. A material of the second gate insulating layer 114 may be the same as a material of the first gate insulating layer 113. The first gate insulating layer 113 and the second gate insulating layer 114 may each include silicon oxide (SiOx). The second gate insulating layer 114 in contact with the upper surface of the second oxide semiconductor layer A2 may have a second thickness t2 in a direction perpendicular to the substrate 100.

The first gate insulating layer 113 in contact with the upper surface of the first oxide semiconductor layer A1 has the first thickness t1 in a direction perpendicular to the substrate 100, and the second gate insulating layer 114 in contact with the upper surface of the second oxide semiconductor layer A2 may have the second thickness t2 in a direction perpendicular to the substrate 100. The first thickness t1 of the first gate insulating layer 113 may be equal to the second thickness t2 of the second gate insulating layer 114. In addition, a difference between the first thickness t1 of the first gate insulating layer 113 and the second thickness t2 of the second gate insulating layer 114 may be 500 Å or less.

Conventionally, when the first oxide semiconductor layer A1 and the second oxide semiconductor layer A2 are doped through ion implantation, a difference in doping concentration between the first oxide semiconductor layer A1 and the second oxide semiconductor layer A2 may be caused by a difference in thickness between the first gate insulating layer 113 on the first oxide semiconductor layer A1 and the second gate insulating layer 114 on the second oxide semiconductor layer A2. Accordingly, it is difficult to simultaneously optimize the resistance values of the first oxide semiconductor layer A1 and the second oxide semiconductor layer A2 to desired levels.

When a difference between the first thickness t1 of the first gate insulating layer 113 in contact with the upper surface of the first oxide semiconductor layer A1 and the second thickness t2 of the second gate insulating layer 114 in contact with the upper surface of the second oxide semiconductor layer A2 is less than 500 Å, a projection anomalous distance of implanted ions may be formed similarly even when heterogeneous oxide semiconductor layers (e.g., the first oxide semiconductor layer A1 and the second oxide semiconductor layer A2) are doped through ion implantation. Therefore, the resistance values of the first oxide semiconductor layer A1 and the second oxide semiconductor layer A2 may be simultaneously formed at desired levels.

When the first oxide semiconductor layer A1 and the second oxide semiconductor layer A2 are doped through ion implantation, the diffusion length of ions doped into the channel region C1 of the first oxide semiconductor layer A1 and the channel region C2 of the second oxide semiconductor layer A2 may be reduced. Accordingly, the effective lengths of the channel region C1 of the first oxide semiconductor layer A1 and the channel region C2 of the second oxide semiconductor layer A2 may be increased. Based on the effective lengths of the channel region C1 of the first oxide semiconductor layer A1 and the channel region C2 of the second oxide semiconductor layer A2, the lengths of the first gate electrode G1 and the second gate electrode G2 for forming the same lengths of the channel region C1 of the first oxide semiconductor layer A1 and the channel region C2 of the second oxide semiconductor layer A2 in the first direction (e.g., the x direction or the −x direction) decrease. Accordingly, it may be advantageous to control the distribution of first and second oxide semiconductor elements and manufacture a high-resolution panel.

In addition, the thickness of the first gate insulating layer 113 and/or the second gate insulating layer 114 on the first oxide semiconductor layer A1 may be reduced, the electric field of the first oxide semiconductor layer A1 may be increased, and thus, more current may flow under the same voltage condition. In particular, electron mobility of the first oxide semiconductor layer A1 may be increased, which may be advantageous in terms of device integration.

The third oxide semiconductor layer A3 may be disposed on the buffer layer 111 and overlap an electrode CE1 formed in the bottom metal layer CAS. The third oxide semiconductor layer A3 may include IGZO and/or ITGZO. Because the third oxide semiconductor layer A3 and the first oxide semiconductor layer A1 may be formed in the same process, the first oxide semiconductor layer A1 and the third oxide semiconductor layer A3 may include the same material as each other. For example, when the first oxide semiconductor layer A1 includes IGZO, the third oxide semiconductor layer A3 may also include IGZO. Alternatively, when the first oxide semiconductor layer A1 includes ITGZO, the third oxide semiconductor layer A3 may also include ITGZO. However, the disclosure is not limited thereto. In another embodiment, the first oxide semiconductor layer A1 may include a material that is different from a material of the third oxide semiconductor layer A3.

The storage capacitor Cst may be disposed on the substrate 100. The storage capacitor Cst may include the lower electrode CE1 and the upper electrode CE2 overlapping each other. In an embodiment, the lower electrode CE1 of the storage capacitor Cst may be a region of the bottom metal layer CAS overlapping the third oxide semiconductor layer A3. In other words, a region of the bottom metal layer CAS overlapping the third oxide semiconductor layer A3 may be the lower electrode CE1 of the storage capacitor Cst. For example, the bottom metal layer CAS overlapping the third oxide semiconductor layer A3 and the lower electrode CE1 of the storage capacitor Cst may be integral with each other. The upper electrode CE2 of the storage capacitor Cst may be the third oxide semiconductor layer A3. In other words, the third oxide semiconductor layer A3 may include the upper electrode CE2 of the storage capacitor Cst. For example, the third oxide semiconductor layer A3 and the upper electrode CE2 of the storage capacitor Cst may be integral with each other. The buffer layer 111 may extend between the upper electrode CE2 and the lower electrode CE1 of the storage capacitor Cst.

The third insulating layer 115 may be disposed on the first gate electrode G1 and the second gate electrode G2 respectively disposed on the first gate insulating layer 113 and the second gate insulating layer 114. The third insulating layer 115 may include an inorganic insulating material, such as silicon nitride, silicon oxynitride, and silicon oxide, and may include a single layer or multiple layers including any of the inorganic insulating materials described above.

The source electrodes and the drain electrodes may be disposed on the third insulating layer 115. The source electrodes and the drain electrodes disposed on the third insulating layer 115 may each include aluminum (Al), copper (Cu), and/or titanium (Ti) and may include a single layer or multiple layers including any of the conducting materials described above. The source electrode disposed on the third insulating layer 115 may be electrically connected to the source region S1 of the first oxide semiconductor layer A1 and the source region S2 of the second oxide semiconductor layer A2, and the drain electrode disposed on the third insulating layer 115 may be electrically connected to the drain region D1 of the first oxide semiconductor layer A1 and the drain region D2 of the second oxide semiconductor layer A2.

A first organic insulating layer 116 may be disposed on the third insulating layer 115. The first organic insulating layer 116 may include an organic insulating material, such as acryl, benzocyclobutene (BCB), and/or hexamethyldisiloxane (HMDSO). Although not illustrated, a connection electrode may be disposed on the first organic insulating layer 116. The connection electrode may include aluminum (Al), copper (Cu), and/or titanium (Ti), and may include a single layer or multiple layers including any of the conductive materials described above. The connection electrode may be electrically connected to a sub-pixel electrode 310 on a second organic insulating layer 117. However, the disclosure is not limited thereto. As illustrated in FIG. 3A, the connection electrode may not be disposed on the first organic insulating layer 116.

The second organic insulating layer 117 may be disposed on the first organic insulating layer 116, which is on the sub-pixel circuit PC including the first transistor T1, the second transistor T2, and the storage capacitor Cst. The second organic insulating layer 117 may include an organic insulating material, such as acryl, BCB, and/or HMDSO. FIGS. 3A and 3B illustrate that two organic insulating layers are between the sub-pixel circuit PC and the sub-pixel electrode 310, but in another embodiment, one organic insulating layer may be between the sub-pixel circuit PC and the sub-pixel electrode 310, or three or more organic insulating layers may be between the sub-pixel circuit PC and the sub-pixel electrode 310, and the sub-pixel circuit PC and the sub-pixel electrode 310 may be electrically connected to each other through a plurality of connection metals or the like.

An organic light-emitting diode OLED may be disposed on the sub-pixel circuit PC. The organic light-emitting diode OLED on the second organic insulating layer 117 may be electrically connected to the sub-pixel circuit PC. The organic light-emitting diode OLED may include the sub-pixel electrode 310, an emission layer 320, and an opposite electrode 330.

The sub-pixel electrode 310 may be formed on the second organic insulating layer 117. The sub-pixel electrode 310 may be formed as a (semi)transparent electrode or a reflective electrode. When the sub-pixel electrode 310 is formed as a (semi)transparent electrode, the sub-pixel electrode 310 may be formed of, for example, indium tin oxide (ITO), indium zinc oxide (IZO), zinc oxide (ZnO), indium oxide (In₂O₃), indium gallium oxide (IGO), or aluminum zinc oxide (AZO). When the sub-pixel electrode 310 is a reflective electrode, a reflective layer may be formed of Ag, Mg, Al, Pt, Pd, Au, Ni, Nd, Ir, Cr, or any compound thereof, and a layer including ITO, IZO, ZnO, or In₂O₃ may be formed on the reflective layer. In an embodiment, the sub-pixel electrode 310 may have a structure in which an ITO layer, an Ag layer, and an ITO layer are sequentially stacked in this stated order. The sub-pixel electrode 310 may be electrically connected through via holes in the first organic insulating layer 116 and the second organic insulating layer 117 to the source electrode or the drain electrode disposed on the third insulating layer 115.

An insulating layer 118 may be disposed on the sub-pixel electrode 310 and the second organic insulating layer 117. The insulating layer 118 may be a pixel defining layer defining an emission area of a pixel. The insulating layer 118 may include an opening exposing at least a portion of the upper surface of the pixel electrode 310 and may cover an edge of the sub-pixel electrode 310. The insulating layer 118 may include an organic insulating material. Alternatively, the insulating layer 118 may include an inorganic insulating material, such as silicon nitride (SiNx), silicon oxynitride (SiON), or silicon oxide (SiOx). Alternatively, the insulating layer 118 may include an organic insulating material and an inorganic insulating material.

The emission layer 320 may be disposed in the opening in the insulating layer 118 and on the sub-pixel electrode 310. The emission layer 320 may include a similar region for each sub-pixel in the display area DA. The emission layer 320 may be patterned to correspond to the sub-pixel electrode 310. Unlike the emission layer 320, a first functional layer and/or a second functional layer may be continuously formed on the substrate 100.

Although not illustrated, the first functional layer may be disposed below the emission layer 320 and the second functional layer may be disposed above the emission layer 320. The emission layer 320 may include a high molecular weight organic material or a low molecular weight organic material that emits light of a desired color.

The first functional layer may be a single layer or layers. For example, when the first functional layer includes a high molecular weight material, the first functional layer may be a single-layered hole transport layer (HTL) and may include polyethylene dihydroxythiophene (PEDOT: poly-(3,4)-ethylene-dihydroxy thiophene) or polyaniline (PANI). When the first functional layer includes a low molecular weight material, the first functional layer may include a hole injection layer (HIL) and an HTL.

The second functional layer may be omitted, but when the first functional layer and the emission layer 320 each include a high molecular weight material, the second functional layer may be desired. The second functional layer may be a single layer or multiple layers. The second functional layer may include an electron transport layer (ETL) and/or an electron injection layer (EIL).

The opposite electrode 330 may include a conductive material having a low work function. For example, the opposite electrode 330 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 330 may further include a layer including ITO, IZO, ZnO, or In₂O₃ on the (semi)transparent layer including the material described above. The opposite electrode 330 may be continuously formed on the substrate 100. The first functional layer, the second functional layer, and the opposite electrode 330 may be formed by thermal evaporation.

Although not illustrated, the organic light-emitting diode OLED may be covered with a thin-film encapsulation layer. The thin-film encapsulation layer may include at least one organic encapsulation layer and at least one inorganic encapsulation layer. Specifically, the thin-film encapsulation layer may include a first inorganic encapsulation layer, a second inorganic encapsulation layer, and an organic encapsulation layer between the first inorganic encapsulation layer and the second inorganic encapsulation layer. In another embodiment, the number of organic encapsulation layers, the number of inorganic encapsulation layers, and the stacking order thereof may be changed.

The first inorganic encapsulation layer and the second inorganic encapsulation layer may each include at least one inorganic material selected from aluminum oxide, titanium oxide, tantalum oxide, hafnium oxide, zinc oxide, silicon oxide, silicon nitride, and silicon oxynitride. The first inorganic encapsulation layer and the second inorganic encapsulation layer may each be a single layer or multiple layers including any of the inorganic materials described above. The organic encapsulation layer may include a polymer-based material. The polymer-based material may include PMMA, acrylic resin (e.g., polyacrylic acid), epoxy-based resin, polyimide, polyethylene, and the like. In an embodiment, the organic encapsulation layer may include acrylate polymer.

The material of the first inorganic encapsulation layer may be different from the material of the second inorganic encapsulation layer. For example, the first inorganic encapsulation layer may include silicon oxynitride and the second inorganic encapsulation layer may include silicon nitride. The thicknesses of the first inorganic encapsulation layer may be different from the thickness of the second inorganic encapsulation layer. The thickness of the first inorganic encapsulation layer may be greater than the thickness of the second inorganic encapsulation layer. Alternatively, the thickness of the second inorganic encapsulation layer may be greater than the thickness of the first inorganic encapsulation layer, or the thicknesses of the first inorganic encapsulation layer may be equal to the thickness of the second inorganic encapsulation layer.

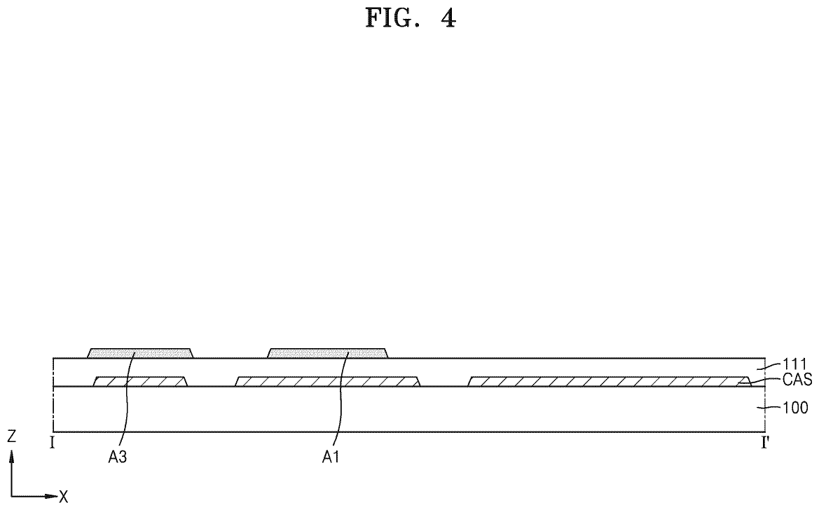

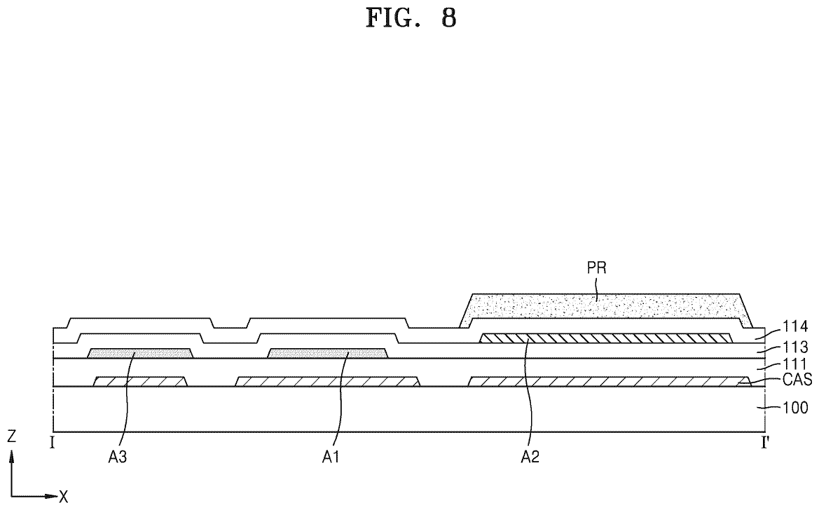

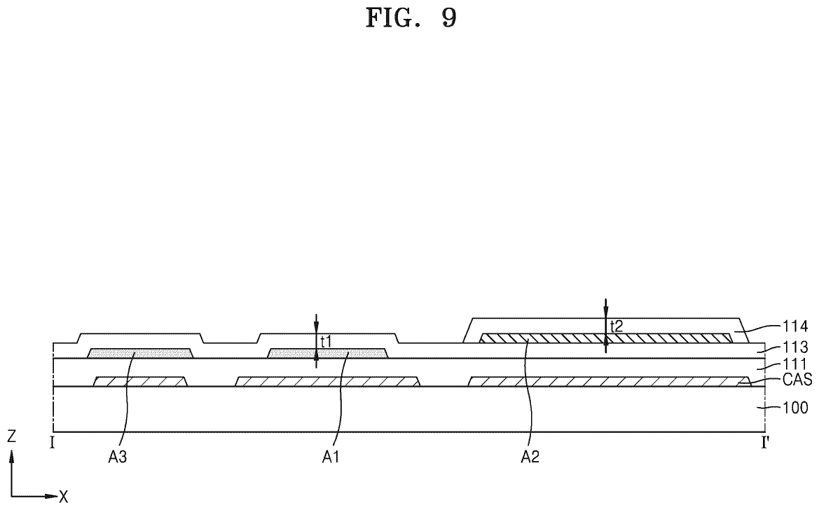

FIGS. 4 to 13 are cross-sectional views schematically illustrating a method of manufacturing a display device, according to an embodiment.

Referring to FIG. 4, a bottom metal layer CAS may be formed on a substrate 100, and a buffer layer 111 may be formed on the bottom metal layer CAS. The buffer layer 111 may be continuously formed on the substrate 100. The buffer layer 111 may include an inorganic insulating material, such as silicon nitride, silicon oxynitride, and silicon oxide, and may include a single layer or layers including the inorganic insulating material described above.

A first oxide semiconductor layer A1 and a third oxide semiconductor layer A3 may be formed on the buffer layer 111. The first oxide semiconductor layer A1 and/or the third oxide semiconductor layer A3 may each include IGZO. Alternatively, the first oxide semiconductor layer and/or the third oxide semiconductor layer may each include ITGZO.

The first oxide semiconductor layer A1 may be disposed to overlap at least a portion of the bottom metal layer CAS formed on the substrate 100. In addition, the third oxide semiconductor layer A3 may be disposed to overlap at least a portion of the bottom metal layer CAS formed on the substrate 100.

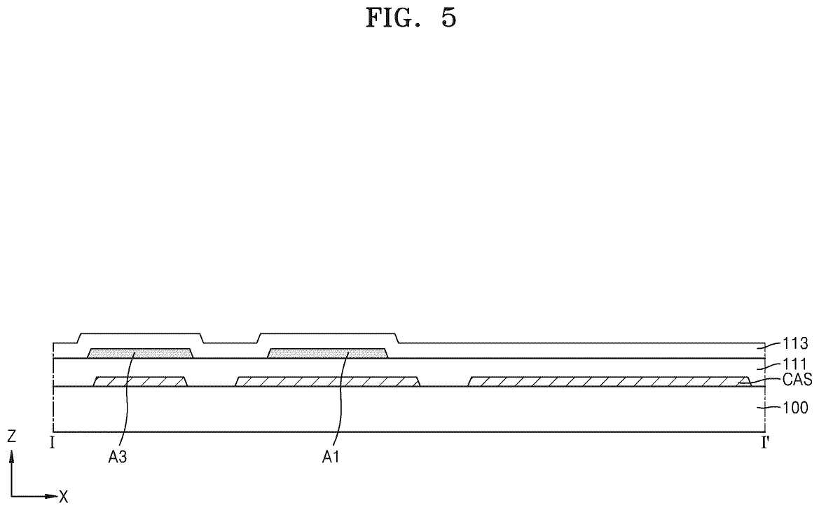

Referring to FIG. 5, a first gate insulating layer 113 may be formed on the first oxide semiconductor layer A1 and the third oxide semiconductor layer A3. The first gate insulating layer 113 may be continuously formed on the substrate 100. The first gate insulating layer 113 may completely cover the upper surface of the first oxide semiconductor layer A1. The first gate insulating layer 113 may completely cover the upper surface of the third oxide semiconductor layer A3. The first gate insulating layer 113 may include silicon oxide (SiOx).

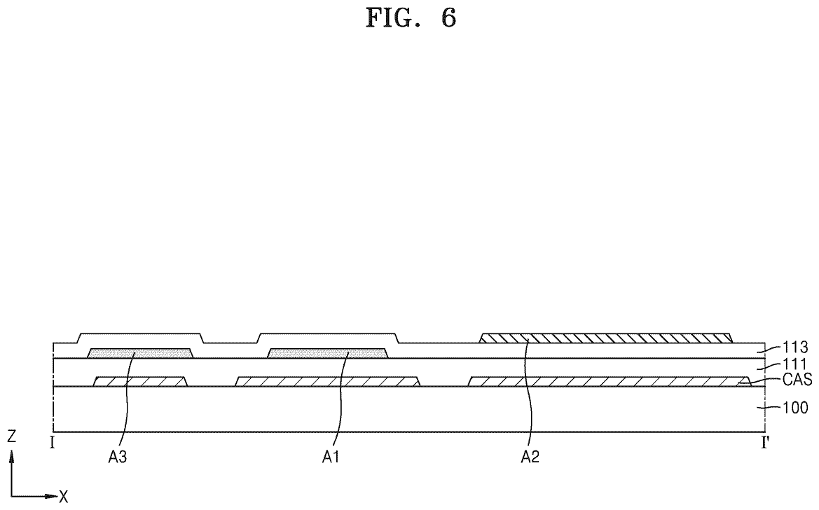

Referring to FIG. 6, a second oxide semiconductor layer A2 may be formed and disposed on the first gate insulating layer 113. The second oxide semiconductor layer A2 may be disposed to overlap at least a portion of the bottom metal layer CAS.

The second oxide semiconductor layer A2 may include a material that is different from a material of the first oxide semiconductor layer A1. For example, when the first oxide semiconductor layer A1 includes IGZO, the second oxide semiconductor layer A2 may include ITGZO. Alternatively, when the first oxide semiconductor layer A1 includes ITGZO, the second oxide semiconductor layer A2 may include IGZO.

Although not illustrated, the second oxide semiconductor layer A2 may have a structure in which a layer including ITGZO and a layer including ITGZO are stacked in multiple layers. Specifically, the second oxide semiconductor layer A2 may include a first layer, a second layer, and a third layer. The second layer may be in contact with the upper surface of the first layer, and the third layer may be in contact with the upper surface of the second layer. The first layer and the third layer may each include IGZO, and the second layer may include ITGZO. However, the disclosure is not limited thereto. The second oxide semiconductor layer A2 may have a stack structure of five layers instead of three layers. The first layer and the third layer may each include ITGZO, and the second layer may include IGZO. In addition, the first oxide semiconductor layer A1 may also have a structure in which a layer including ITGZO and a layer including ITGZO are stacked in multiple layers.

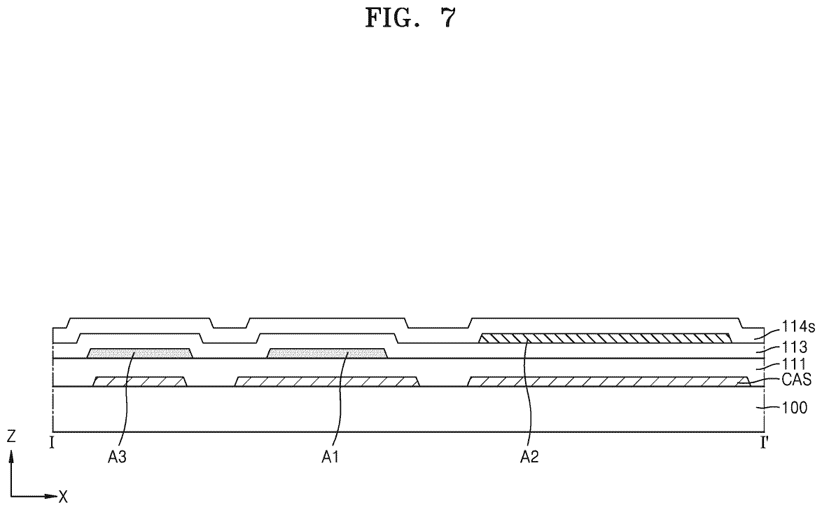

Referring to FIGS. 7 to 9, a second gate insulating layer forming material 114s may be disposed on the second oxide semiconductor layer A2. The second gate insulating layer forming material 114s may be continuously formed on the substrate 100. The second gate insulating layer forming material 114s may include the same material as the material of the first gate insulating layer 113. The second gate insulating layer forming material 114s may include silicon oxide (SiOx).

A photoresist PR may be disposed on a portion of the second gate insulating layer forming material 114s overlapping the second oxide semiconductor layer A2. A second gate insulating layer 114 may be formed by etching a portion of the second gate insulating layer forming material 114s on which the photoresist PR is not disposed. The second gate insulating layer forming material 114s below the photoresist PR may remain without being etched in the etching process. After that, the photoresist PR may be removed.

Because a portion of the second gate insulating layer forming material 114s is etched, the second gate insulating layer 114 may not be continuous across the area of the substrate 100. The second gate insulating layer 114 may be formed to completely cover the upper surface of the second oxide semiconductor layer A2. Specifically, the second gate insulating layer 114 may be formed to cover the upper surface and the side surface of the second oxide semiconductor layer A2.

The first portion of the gate insulating layer 113 covering the upper surface of the first oxide semiconductor layer A1 may have a first thickness t1 in a direction perpendicular to the substrate 100. The second gate insulating layer 114 covering the upper surface of the second oxide semiconductor layer A2 may have a second thickness t2 in a direction perpendicular to the substrate 100. The first thickness t1 of the first gate insulating layer 113 may be equal to the second thickness t2 of the second gate insulating layer 114. Alternatively, a difference between the first thickness t1 of the first gate insulating layer 113 and the second thickness t2 of the second gate insulating layer 114 may be 500 Å or less.

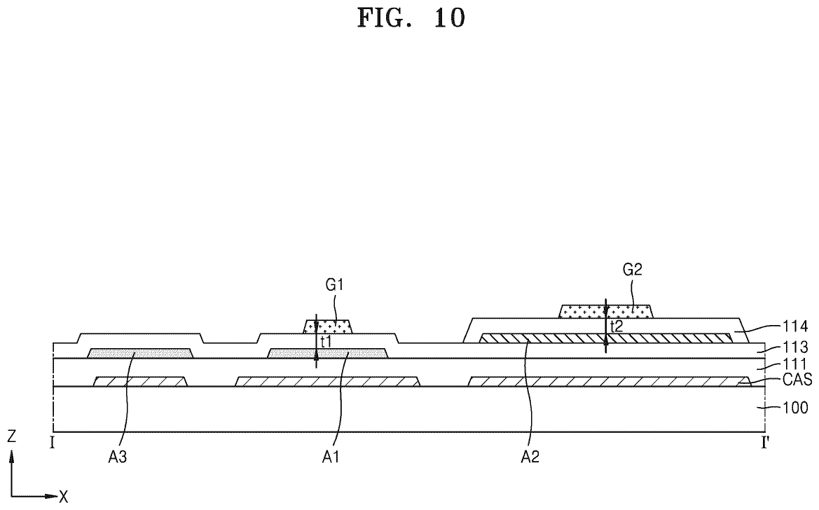

Referring to FIG. 10, a first gate electrode G1 may be formed on the first gate insulating layer 113. The first gate electrode G1 may be formed on the first gate insulating layer 113 to overlap at least a portion of the first oxide semiconductor layer A1. Specifically, the first gate electrode G1 may be formed to overlap a channel region C1 of the first oxide semiconductor layer A1. A second gate electrode G2 may also be formed on the second gate insulating layer 114. The second gate electrode G2 may be formed on the second gate insulating layer 114 to overlap at least a portion of the second oxide semiconductor layer A2. Specifically, the second gate electrode G2 may be formed to overlap a channel region C2 of the second oxide semiconductor layer A2. The first gate electrode G1 and the second gate electrode G2 may each include a conductive material including molybdenum (Mo), aluminum (Al), copper (Cu), titanium (Ti), and the like, and may include a single layer or multiple layers including any of the conductive materials described above.

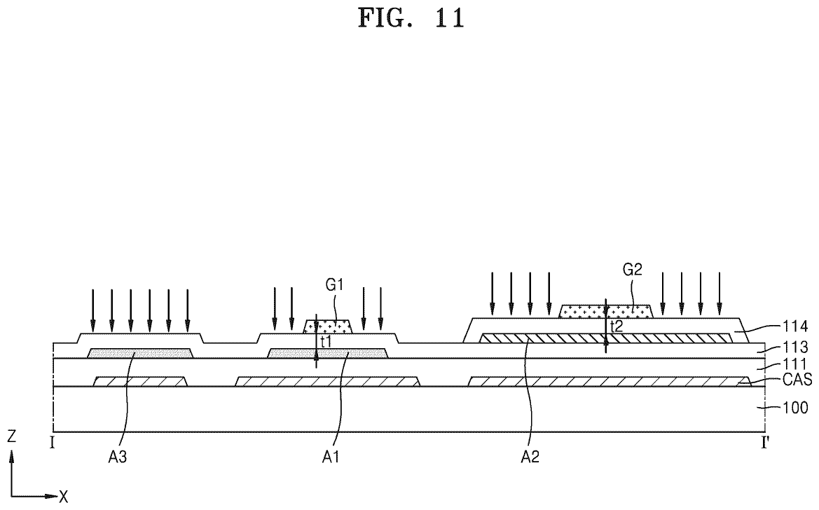

Referring to FIG. 11, at least a portion of the first oxide semiconductor layer A1, at least a portion of the second oxide semiconductor layer A2, and the third oxide semiconductor layer A3 may be doped through ion implantation. A portion of the first oxide semiconductor layer A1 that does not overlap the first gate electrode G1 may be doped. In other words, the other portions of the first oxide semiconductor layer A1 except for the channel region C1 may be doped. A portion of the second oxide semiconductor layer A2 that does not overlap the second gate electrode G2 may be doped. In other words, the other portions of the second oxide semiconductor layer A2 except for the channel region C2 may be doped. Because a gate electrode or the like is not disposed on the third oxide semiconductor layer A3, the entirety of the third oxide semiconductor layer A3 may be doped.

Conventionally, the first gate insulating layer and the second gate insulating layer are continuously formed on the substrate, but the first oxide semiconductor layer is in contact with the upper surface of the buffer layer, and the second oxide semiconductor layer is on the first gate insulating layer disposed on the buffer layer. Accordingly, the first gate insulating layer and the continuous second gate insulating layer disposed on the first oxide semiconductor layer has a different thickness, e.g., is thicker than, the continuous second gate insulating layer that is alone on the second oxide semiconductor layer. Specifically, the first gate insulating layer and the second gate insulating layer may be continuously formed on the first oxide semiconductor layer A1, but only the second gate insulating layer is formed on the second oxide semiconductor layer, and thus, the first gate insulating layer or the second gate insulating layer disposed on the first oxide semiconductor layer and the second oxide semiconductor layer has a different thickness. When the first oxide semiconductor layer and the second oxide semiconductor layer are doped through ion implantation, a difference in doping concentration between the first gate insulating layer and the second gate insulating layer may be caused by a difference in thickness between the first gate insulating layer and the second gate insulating layer disposed on the first oxide semiconductor layer and the second oxide semiconductor layer. Accordingly, it is difficult to simultaneously optimize the resistance values of the first oxide semiconductor layer and the second oxide semiconductor layer to desired levels.

When a difference between the first thickness t1 of the first gate insulating layer 113 in contact with the upper surface of the first oxide semiconductor layer A1 and the second thickness t2 of the second gate insulating layer 114 in contact with the upper surface of the second oxide semiconductor layer A2 is less than 500 Å, a projection anomalous distance of implanted ions may be formed similarly even when heterogeneous oxide semiconductor layers (e.g., the first oxide semiconductor layer A1 and the second oxide semiconductor layer A2) are simultaneously doped through ion implantation. Therefore, the resistance values of the first oxide semiconductor layer A1 and the second oxide semiconductor layer A2 may be simultaneously formed to desired levels. When the thickness of the first gate insulating layer 113 or the second gate insulating layer 114 disposed on the first oxide semiconductor layer A1 and the second oxide semiconductor layer A2 is similar, the resistance values of the first oxide semiconductor layer A1 and the second oxide semiconductor layer A2 may be simultaneously formed to desired levels by doping the first oxide semiconductor layer A1 and the second oxide semiconductor layer A2 at the same time by ion implantation. Through a single doping process, the resistance values of the first oxide semiconductor layer A1 and the second oxide semiconductor layer A2 may be simultaneously formed to desired levels.

When the first oxide semiconductor layer A1 and the second oxide semiconductor layer A2 are doped through ion implantation, the diffusion length of ions implanted into the channel region C1 of the first oxide semiconductor layer A1 and the channel region C2 of the second oxide semiconductor layer A2 is reduced, compared to a process of etching the first gate insulating layer 113 or the second gate insulating layer 114 and doping the first gate insulating layer 113 or the second gate insulating layer 114 by hydrogen (H2) diffusion. Accordingly, the effective lengths of the channel region C1 of the first oxide semiconductor layer A1 and the channel region C2 of the second oxide semiconductor layer A2 may be increased. In addition, in the process of doping the first oxide semiconductor layer A1 and the second oxide semiconductor layer A2 through ion implantation, a portion of the first oxide semiconductor layer A1 that does not overlap the first gate electrode G1 and a portion of the second oxide semiconductor layer A2 that does not overlap the second gate electrode G2 may be doped through ion implantation. Based on the effective lengths of the channel region C1 of the first oxide semiconductor layer A1 and the channel region C2 of the second oxide semiconductor layer A2, the lengths of the first gate electrode G1 and the second gate electrode G2 for forming the same lengths of the channel region C1 of the first oxide semiconductor layer A1 and the channel region C2 of the second oxide semiconductor layer A2 in the first direction (e.g., the x direction or the −x direction) decrease. Accordingly, a fabrication process in accordance with an embodiment of the current disclosure may be advantageous for control of the distribution of first and second oxide semiconductor elements and therefore advantageous for manufacture a high-resolution display panel.

In addition, because the second gate insulating layer 114 is disposed to cover only the upper surface or the side surface of the second oxide semiconductor layer A2, the second gate insulating layer 114 may not be disposed on the first oxide semiconductor layer A1, and only the first gate insulating layer 113 may be disposed on the first oxide semiconductor layer A1. Instead of continuously forming the first gate insulating layer 113 and the second gate insulating layer 114 on the first oxide semiconductor layer A1, only the first gate insulating layer 113 may be disposed on the first oxide semiconductor layer A1. The thickness of the first gate insulating layer 113 or the second gate insulating layer 114 on the first oxide semiconductor layer A1 may be reduced, and the electric field that gate electrode G1 applies to the first oxide semiconductor layer A1 may be increased, and thus, the first transistor T1 may provide more current may flow under the same voltage condition. Accordingly, electron mobility of the first oxide semiconductor layer A1 may be increased. The thickness t1 of the first gate insulating layer 113 or the second gate insulating layer 114 on the first oxide semiconductor layer A1 may be reduced, and current and electron mobility may increase for the same device size of transistor T1, which may be advantageous in terms of device integration and miniaturization.

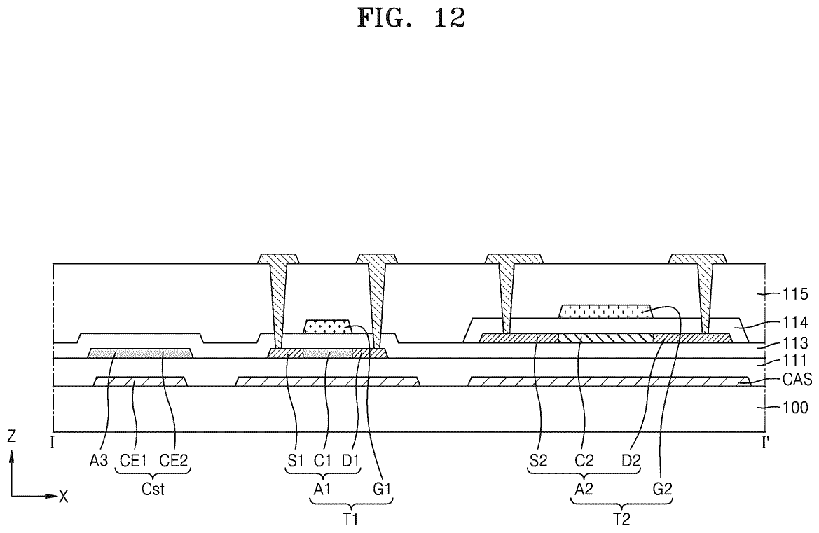

Referring to FIG. 12, a third insulating layer 115 may be formed on the first gate electrode G1 and the second gate electrode G2. The third insulating layer 115 may include an inorganic insulating material, such as silicon nitride, silicon oxynitride, and silicon oxide, and may include a single layer or multiple layers including any of the inorganic insulating materials described above. Source electrodes and drain electrodes may be formed on the third insulating layer 115. The source electrode on the third insulating layer 115 may be electrically connected to the source region S1 of the first oxide semiconductor layer A1 and the source region S2 of the second oxide semiconductor layer A2, and the drain electrode on the third insulating layer 115 may be electrically connected to the drain region D1 of the first oxide semiconductor layer A1 and the drain region D2 of the second oxide semiconductor layer A2.

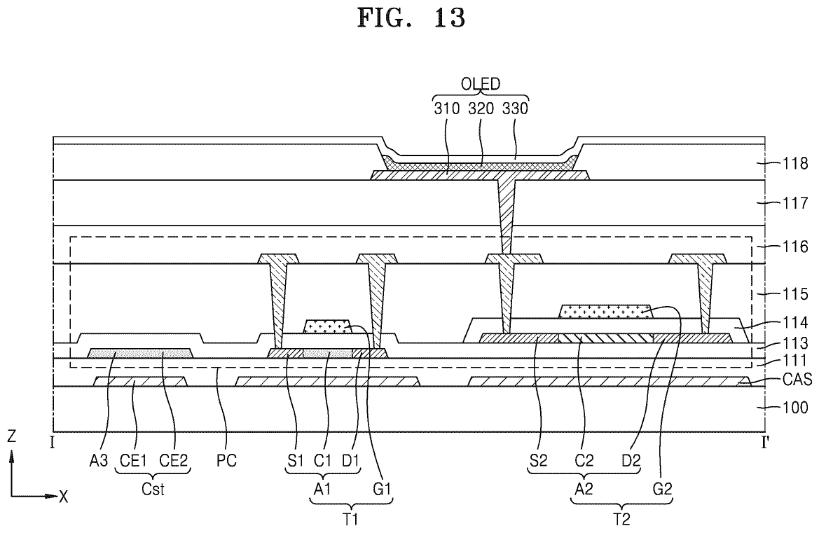

Referring to FIG. 13, a first organic insulating layer 116 and a second organic insulating layer 117 may be formed on the third insulating layer 115. The first organic insulating layer 116 and the second organic insulating layer 117 may each include an organic insulating material, such as acryl, BCB, and/or HMDSO.

An insulating layer 118 may be formed on the second organic insulating layer 117. The insulating layer 118 may include an organic insulating material. Alternatively, the third organic insulating layer 118 may include an inorganic insulating material, such as silicon nitride (SiNₓ), silicon oxynitride (SiON), or silicon oxide (SiOₓ). Alternatively, the insulating layer 118 may include an organic insulating material and an inorganic insulating material.

An organic light-emitting diode OLED may be formed on the second organic insulating layer 117. The organic light-emitting diode OLED may include a sub-pixel electrode 310, an emission layer 320, and an opposite electrode 330. When the sub-pixel electrode 310 is formed as a (semi)transparent electrode, the sub-pixel electrode 310 may be formed of, for example, ITO, IZO, ZnO, In₂O₃, IGO, or AZO. When the sub-pixel electrode 310 is formed as a reflective electrode, a reflective layer may be formed of Ag, Mg, Al, Pt, Pd, Au, Ni, Nd, Ir, Cr, or any compound thereof, and a layer including ITO, IZO, ZnO, or In₂O₃ may be formed on the reflective layer. In an embodiment, the sub-pixel electrode 310 may have a structure in which an ITO layer, an Ag layer, and an ITO layer are sequentially stacked in this stated order. At least a portion of the sub-pixel electrode 310 may be exposed through an opening defined in the insulating layer 118. The emission layer 320 may be formed on the sub-pixel electrode 310. The emission layer 320 may be arranged in the opening of the insulating layer 118. The emission layer 320 may include a high molecular weight organic material or a low molecular weight organic material that emits light of a desired color. The opposite electrode 330 may be continuously formed on the substrate 100. The opposite electrode 330 may include a conductive material having a low work function. For example, the opposite electrode 330 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 330 may further include a layer including ITO, IZO, ZnO, or In₂O₃ on the (semi)transparent layer including the material described above.

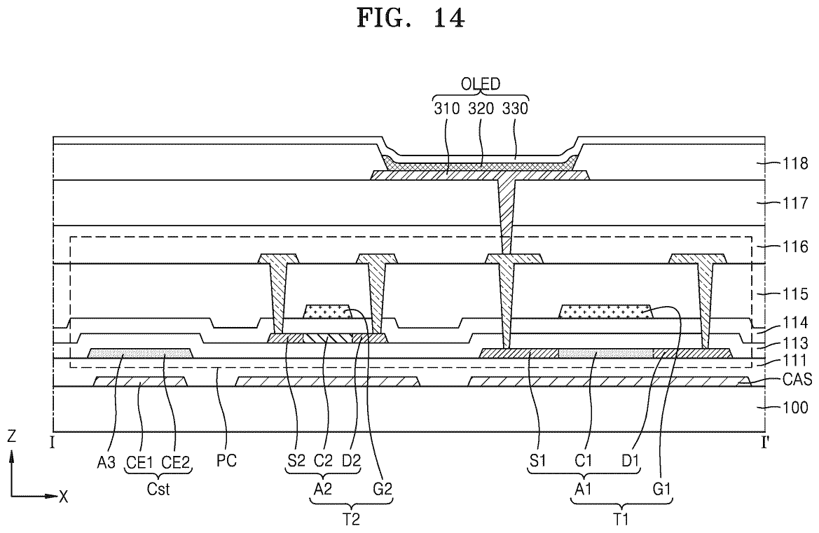

FIG. 14 is a cross-sectional view schematically illustrating a portion of a display device according to an embodiment where the second gate insulating layer 114 extends over the first oxide semiconductor layer A1. Specifically, FIG. 14 is a schematic cross-sectional view of the display device 1 of FIG. 1A taken along line I-I′ of FIG. 1A.

Referring to FIG. 14, a bottom metal layer CAS may be disposed on the substrate 100. A buffer layer 111 may be disposed on the bottom metal layer CAS. Because the substrate 100, the bottom metal layer CAS, and the buffer layer 111 have been described above with reference to FIGS. 3A and 3B, details thereof are omitted.

A sub-pixel circuit PC may be disposed on the buffer layer 111. The sub-pixel circuit PC may include a first transistor T1, a second transistor T2, and a storage capacitor Cst. However, the disclosure is not limited thereto.

The first transistor T1 may include a first oxide semiconductor layer A1 disposed on the substrate 100 and a first gate electrode G1 overlapping a channel region C1 of the first oxide semiconductor layer A1. The first oxide semiconductor layer A1 may be disposed on the buffer layer 111.

The first oxide semiconductor layer A1 may include IGZO or ITGZO. When the first oxide semiconductor layer A1 of the first transistor T1 includes ITGZO that is a high electron mobility material, the first transistor T1 may function as a switching transistor. Alternatively, when the first oxide semiconductor layer A1 of the first transistor T1 includes IGZO that is a low electron mobility material, the first transistor T1 may function as a driving transistor.

The first oxide semiconductor layer A1 may include a channel region C1, a source region S1, and a drain region D1, the source region S1 and the drain region D1 being spaced apart from each other with the channel region C1 therebetween. The source region S1 of the first oxide semiconductor layer A1 may be connected to a source electrode disposed on a third insulating layer 115, and the drain region D1 of the first oxide semiconductor layer A1 may be connected to a drain electrode disposed on the third insulating layer 115. The source region S1 and the drain region D1 of the first oxide semiconductor layer A1 may include impurities at a higher concentration than the channel region C1. Specifically, the source region S1 and the drain region D1 of the first oxide semiconductor layer A1 may include receive more ion doping. The source region S1 and the drain region D1 of the first oxide semiconductor layer A1 may include boron or fluorine as dopants.

The first gate electrode G1 may be disposed on the first gate insulating layer 113 and the second gate insulating layer 114. The first gate insulating layer 113 and the second gate insulating layer 114 may be between the first gate electrode G1 and the first oxide semiconductor layer A1. The first gate electrode G1 may be disposed to overlap the channel region C1 of the first oxide semiconductor layer A1. The first gate electrode G1 may include a conductive material including molybdenum (Mo), aluminum (Al), copper (Cu), titanium (Ti), and the like, and may include a single layer or layers including the conductive material described above.

The second transistor T2 may include the second oxide semiconductor layer A2 on the substrate 100 and a second gate electrode G2 overlapping a channel region C2 of the second oxide semiconductor layer A2. Specifically, the second oxide semiconductor layer A2 may be disposed on the first gate insulating layer 113. The second oxide semiconductor layer A2 may be between the first gate insulating layer 113 and a second gate insulating layer 114.

The second oxide semiconductor layer A2 may include a material that is different from a material of the first oxide semiconductor layer A1. When the first oxide semiconductor layer A1 includes IGZO, the second oxide semiconductor layer A2 may include ITGZO that is different from a material of the first oxide semiconductor layer A1. When the second oxide semiconductor layer A2 includes ITGZO that is a high electron mobility material, the second transistor T2 may function as a switching transistor. In addition, when the first oxide semiconductor layer A1 includes ITGZO, the second oxide semiconductor layer A2 may include IGZO that is different from a material of the first oxide semiconductor layer A1. Alternatively, when the second oxide semiconductor layer A2 includes IGZO that is a low electron mobility material, the second transistor T2 may function as a driving transistor.

The second oxide semiconductor layer A2 may include a channel region C2, a source region S2, and a drain region D2, the source region S2 and the drain region D2 being spaced apart from each other with the channel region C2 therebetween. The source region S2 of the second oxide semiconductor layer A2 may be connected to a source electrode disposed on the third insulating layer 115, and the drain region D2 of the second oxide semiconductor layer A2 may be connected to a drain electrode disposed on the third insulating layer 115. The source region S2 and the drain region D2 of the second oxide semiconductor layer A2 may include impurities at a higher concentration than the channel region C2 of the second oxide semiconductor layer A2. Specifically, the source region S2 and the drain region D2 of the second oxide semiconductor layer A2 may include doped ions. The source region S2 and the drain region D2 of the second oxide semiconductor layer A2 may include boron or fluorine as a dopant.

The second gate electrode G2 may be disposed on the second gate insulating layer 114 and overlap the channel region C2 of the second oxide semiconductor layer A2. The second gate electrode G2 may include a conductive material including molybdenum (Mo), aluminum (Al), copper (Cu), titanium (Ti), and the like, and may include a single layer or multiple layers including any of the conductive materials described above.

The storage capacitor Cst may be disposed on the substrate 100. The storage capacitor Cst may include a lower electrode CE1 and an upper electrode CE2 overlapping each other. In an embodiment, the lower electrode CE1 of the storage capacitor Cst may include a portion of the bottom metal layer CAS overlapping the third oxide semiconductor layer A3. In other words, the bottom metal layer CAS overlapping the third oxide semiconductor layer A3 may include the lower electrode CE1 of the storage capacitor Cst. For example, the bottom metal layer CAS overlapping the third oxide semiconductor layer A3 and the lower electrode CE1 of the storage capacitor Cst may be integral with each other. The upper electrode CE2 of the storage capacitor Cst may be the third oxide semiconductor layer. In other words, the third oxide semiconductor layer A3 may include the upper electrode CE2 of the storage capacitor Cst. For example, the third oxide semiconductor layer A3 and the upper electrode CE2 of the storage capacitor Cst may be integral with each other. The buffer layer 111 may be between the upper electrode CE2 and the lower electrode CE1 of the storage capacitor Cst.

The first gate insulating layer 113 may be disposed on the first oxide semiconductor layer A1 and/or the third oxide semiconductor layer A3. The first gate insulating layer 113 may be continuously disposed on the substrate 100 and completely cover the upper surface of the first oxide semiconductor layer A1. The first gate insulating layer 113 may include silicon oxide (SiOₓ). However, the disclosure is not limited thereto.

The second gate insulating layer 114 may be disposed on the first gate insulating layer 113. The second gate insulating layer 114 may be continuously disposed on the substrate 100 and completely cover the upper surface of the second oxide semiconductor layer A2. The second gate insulating layer 114 may include silicon oxide (SiOₓ). However, the disclosure is not limited thereto.

The first gate insulating layer 113 and the second gate insulating layer 114, which are continuously formed on the substrate 100, may be continuously disposed on the first oxide semiconductor layer A1. Because the second oxide semiconductor layer A2 is disposed on the first gate insulating layer 113, only the second gate insulating layer 114 may be disposed on the second oxide semiconductor layer A2. The second oxide semiconductor layer A2 may be between the first gate insulating layer 113 and a second gate insulating layer 114. The first gate insulating layer 113 or the second gate insulating layer 114 disposed on the first oxide semiconductor layer A1 and the second oxide semiconductor layer A2 may have a different thickness.

A third insulating layer 115 may be disposed on the first gate electrode G1 and the second gate electrode G2. The third insulating layer 115 may include an inorganic insulating material, such as silicon nitride, silicon oxynitride, and silicon oxide, and may include a single layer or layers including the inorganic insulating material described above.

Source electrodes and drain electrodes may be disposed on the third insulating layer 115. The source electrodes and the drain electrodes on the third insulating layer 115 may each include aluminum (Al), copper (Cu), and/or titanium (Ti), and may include a single layer or layers including the material described above. The source electrode on the third insulating layer 115 may be electrically connected to the source region S1 of the first oxide semiconductor layer A1 and the source region S2 of the second oxide semiconductor layer A2, and the drain electrode on the third insulating layer 115 may be electrically connected to the drain region D1 of the first oxide semiconductor layer A1 and the drain region D2 of the second oxide semiconductor layer A2.

A first organic insulating layer 116 and a second organic insulating layer 117 may be disposed on the third insulating layer 115. The first organic insulating layer 116 and the second organic insulating layer 117 may each include an organic insulating material, such as acryl, BCB, and HMDSO.

An insulating layer 118 may be disposed on the second organic insulating layer 117. The insulating layer 118 may include an organic insulating material. Alternatively, the insulating layer 118 may include an inorganic insulating material, such as silicon nitride (SiNₓ), silicon oxynitride (SiON), or silicon oxide (SiOₓ). Alternatively, the insulating layer 118 may include an organic insulating material and an inorganic insulating material.

An organic light-emitting diode OLED may be disposed on the second organic insulating layer 117. The organic light-emitting diode OLED may include a sub-pixel electrode 310, an emission layer 320, and an opposite electrode 330. When the sub-pixel electrode 310 is formed as a (semi)transparent electrode, the sub-pixel electrode 310 may be formed of, for example, ITO, IZO, ZnO, In₂O₃, IGO, or AZO. When the sub-pixel electrode 310 is formed as a reflective electrode, a reflective layer may be formed of Ag, Mg, Al, Pt, Pd, Au, Ni, Nd, Ir, Cr, or any compound thereof, and a layer including ITO, IZO, ZnO, or In₂O₃ may be formed on the reflective layer. In an embodiment, the sub-pixel electrode 310 may have a structure in which an ITO layer, an Ag layer, and an ITO layer are sequentially stacked in this stated order. At least a portion of the sub-pixel electrode 310 may be exposed through an opening defined in the insulating layer 118. The emission layer 320 may be disposed on the sub-pixel electrode 310. The emission layer 320 may be arranged in the opening of the insulating layer 118. The emission layer 320 may include a high molecular weight organic material or a low molecular weight organic material that emits light of a desired color. The opposite electrode 330 may be continuously formed on the substrate 100. The opposite electrode 330 may include a conductive material having a low work function. For example, the opposite electrode 330 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 330 may further include a layer including ITO, IZO, ZnO, or In₂O₃ on the (semi)transparent layer including the material described above.

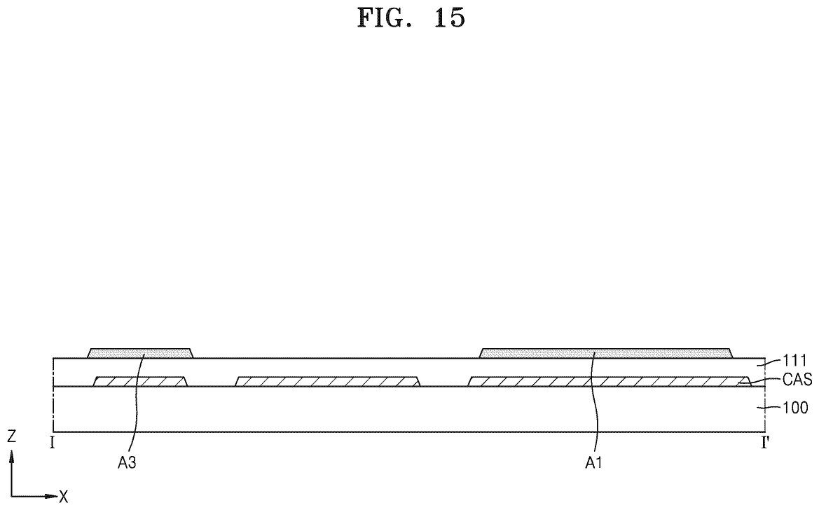

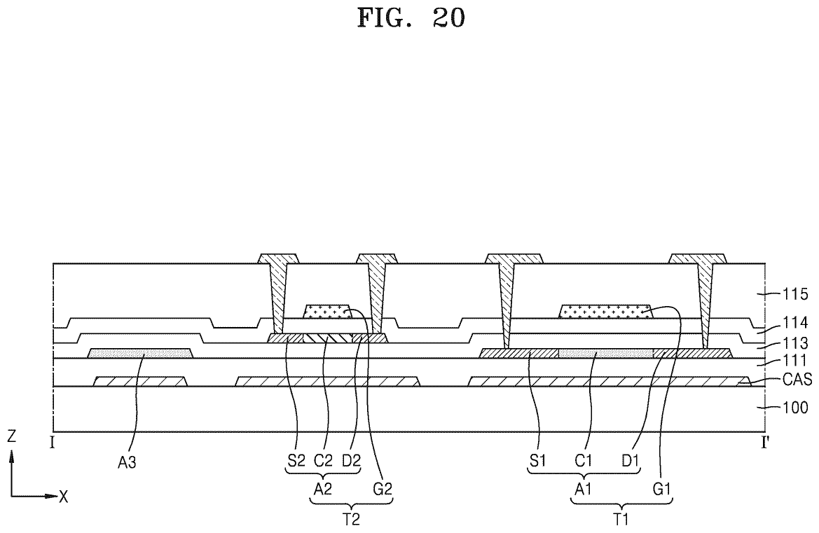

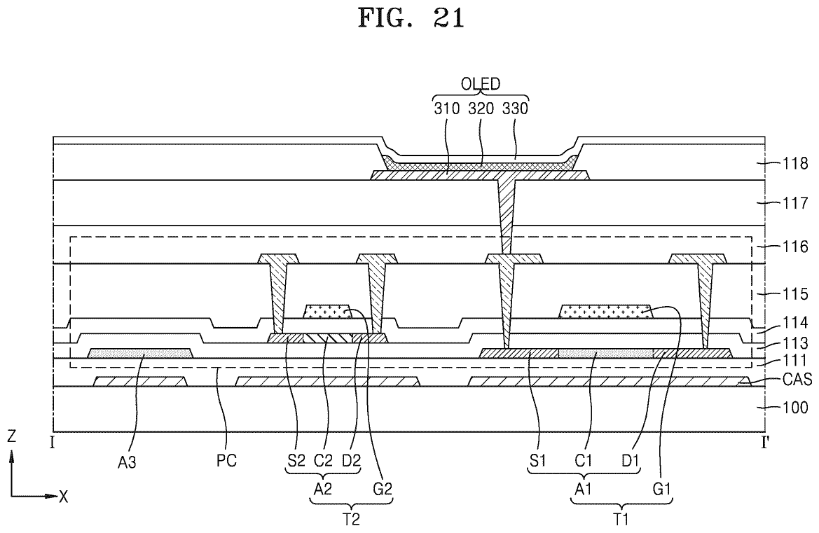

FIGS. 15 to 21 are cross-sectional views schematically illustrating a method of manufacturing a display device, according to an embodiment.

Referring to FIG. 15, a bottom metal layer CAS may be formed on a substrate 100, and a buffer layer 111 may be formed on the bottom metal layer CAS. The buffer layer 111 may be continuously formed on the substrate 100. The buffer layer 111 may include an inorganic insulating material, such as silicon nitride, silicon oxynitride, and silicon oxide, and may include a single layer or multiple layers including any of the inorganic insulating material described above.

A first oxide semiconductor layer A1 and a third oxide semiconductor layer A3 may be formed on the buffer layer 111. The first oxide semiconductor layer A1 and/or the third oxide semiconductor layer A3 may each include IGZO. Alternatively, the first oxide semiconductor layer A1 and/or the third oxide semiconductor layer A3 may each include ITGZO.

The first oxide semiconductor layer A1 may be disposed to overlap at least a portion of the bottom metal layer CAS formed on the substrate 100. In addition, the third oxide semiconductor layer A3 may be disposed to overlap at least a portion of the bottom metal layer CAS formed on the substrate 100.

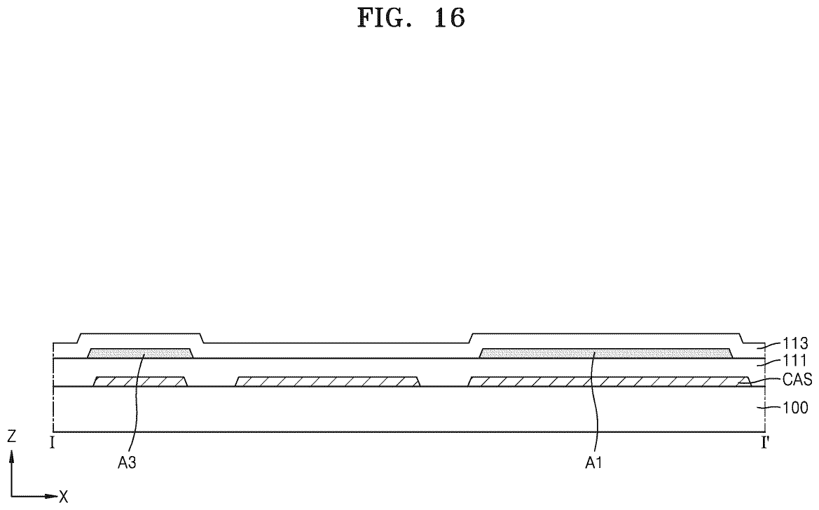

Referring to FIG. 16, a first gate insulating layer 113 may be formed on the first oxide semiconductor layer A1 and the third oxide semiconductor layer A3. The first gate insulating layer 113 may be continuously formed on the substrate 100. The first gate insulating layer 113 may completely cover the upper surface of the first oxide semiconductor layer A1. The first gate insulating layer 113 may completely cover the upper surface of the third oxide semiconductor layer A3. The first gate insulating layer 113 may include an inorganic insulating material such as silicon oxide (SiOₓ).

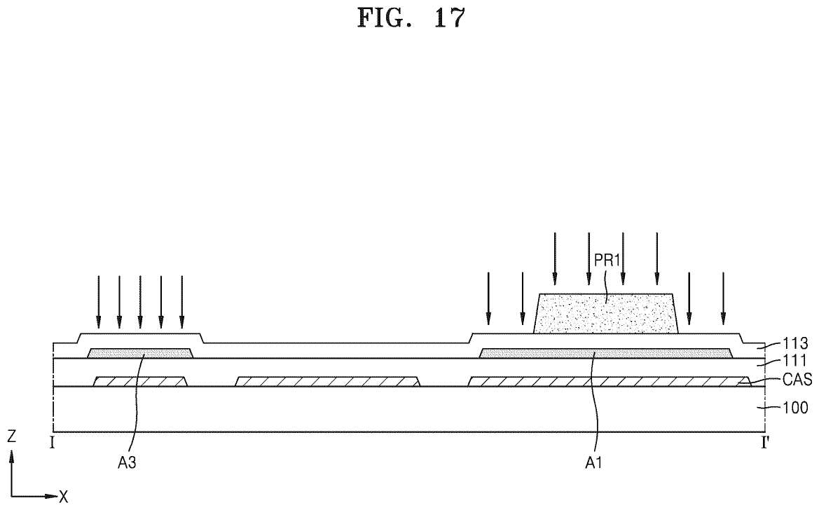

Referring to FIG. 17, a photoresist PR may be formed on the first gate insulating layer 113. The photoresist PR may be formed to overlap at least a portion of the first oxide semiconductor layer A1. In other words, the photoresist PR1 may be formed so that a region of the photoresist PR1 overlaps a channel region C1 of the first oxide semiconductor layer A1.

After the photoresist PR1 overlapping at least a portion of the first oxide semiconductor layer A1 is formed on the first gate insulating layer 113, at least a portion of the first oxide semiconductor layer A1 and the third oxide semiconductor layer A3 may be doped through ion implantation. Specifically, a portion of the first oxide semiconductor layer A1 that does not overlap the photoresist PR1 may be doped through ion implantation. A portion of the first oxide semiconductor layer A1 except for the channel region C1 may be doped through ion implantation. Because none of the photoresist PR1 is on the third oxide semiconductor layer A3, the entirety of the third oxide semiconductor layer A3 may be doped through ion implantation.

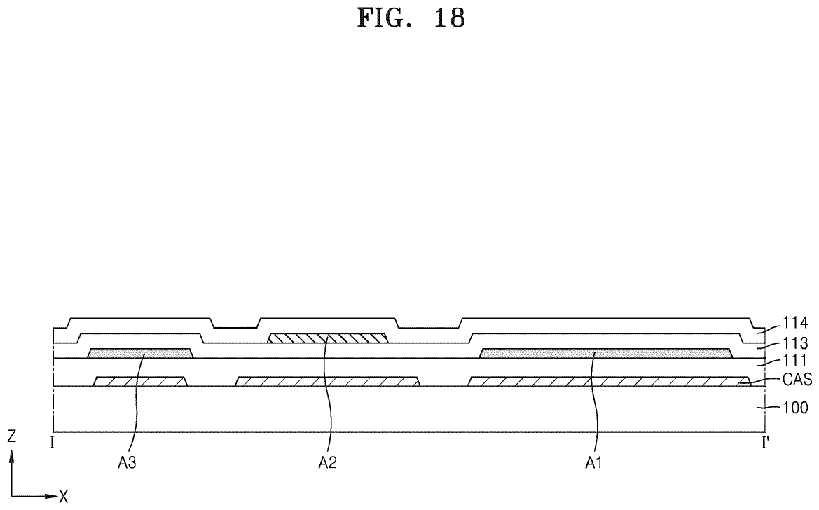

Referring to FIG. 18, the photoresist PR1 may be removed, and a second oxide semiconductor layer A2 may be formed on the first gate insulating layer 113. The second oxide semiconductor layer A2 may include a material that is different from a material of the first oxide semiconductor layer A1. For example, when the first oxide semiconductor layer A1 includes IGZO, the second oxide semiconductor layer A2 may include ITGZO that is different from a material of the first oxide semiconductor layer A1. In addition, when the first oxide semiconductor layer A1 includes ITGZO, the second oxide semiconductor layer A2 may include IGZO that is different from a material of the first oxide semiconductor layer A1.

A second gate insulating layer 114 may be formed on the second oxide semiconductor layer A2. The second gate insulating layer 114 may be continuously formed on the substrate 100 to completely cover the upper surface of the second oxide semiconductor layer A2 and the first gate insulating layer 113. A material of the second gate insulating layer 114 may be the same as a material of the first gate insulating layer 113. The second gate insulating layer 114 may include silicon oxide (SiOₓ). However, the disclosure is not limited thereto.

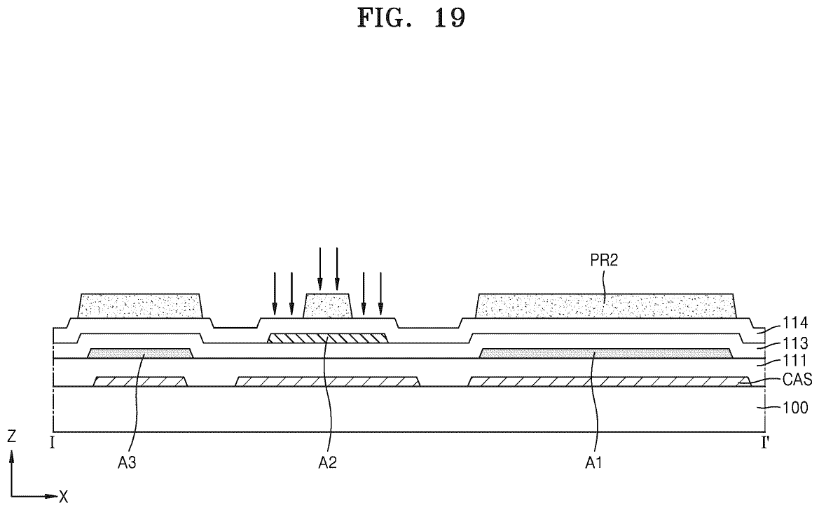

Referring to FIG. 19, a photoresist PR2 may be formed on the second gate insulating layer 114. The photoresist PR2 may be patterned to overlap the entirety of the first oxide semiconductor layer A1. The photoresist PR2 may also overlap the entirety of the third oxide semiconductor layer A3. In addition, the photoresist PR2 may be formed to overlap at least a portion of the second oxide semiconductor layer A2. In particular, the photoresist PR2 may overlap the channel region C2 of the second oxide semiconductor layer A2.

At least a portion of the second oxide semiconductor layer A2 may be doped through ion implantation. Specifically, a portion of the second oxide semiconductor layer A2 that does not overlap the photoresist PR2 may be doped through ion implantation. A portion of the second oxide semiconductor layer A2 except for the channel region C2 may be doped through ion implantation. However, because the photoresist PR2 overlaps the entirety of the first oxide semiconductor layer A1 and the entirety of the third oxide semiconductor layer A3, the entirety of the first oxide semiconductor layer A1 and the entirety of the third oxide semiconductor layer A3 may not be doped because the photoresist PR2 prevents ions from being implanted into regions underlying the photoresist PR2.

Even when the first gate insulating layer 113 or the second gate insulating layer 114 on the first oxide semiconductor layer A1 and the second oxide semiconductor layer A2 has a different thickness, the resistance values of the first oxide semiconductor layer A1 and the second oxide semiconductor layer A2 may be formed to desired levels through ion implantation by disposing the photoresist PR1 on at least a portion of the first oxide semiconductor layer A1, performing primary doping on the first oxide semiconductor layer A1 through ion implantation, disposing the photoresist PR2 on at least a portion of the second oxide semiconductor layer A2, and performing secondary doping on the second oxide semiconductor layer A2 through ion implantation.

Conventionally, the first gate insulating layer and the second gate insulating layer may be continuously formed on the first oxide semiconductor layer, but only the second gate insulating layer is formed on the second oxide semiconductor layer, and thus, the first gate insulating layer or the second gate insulating layer on the first oxide semiconductor layer and the second oxide semiconductor layer has a different thickness. When the first oxide semiconductor layer and the second oxide semiconductor layer are simultaneously doped by ion implantation, a difference in doping concentration between the first gate insulating layer and the second gate insulating layer may be caused by a difference in thickness between the first gate insulating layer and the second gate insulating layer disposed on the first oxide semiconductor layer and the second oxide semiconductor layer. Accordingly, it is difficult to simultaneously optimize the resistance values of the first oxide semiconductor layer and the second oxide semiconductor layer to desired levels.

According to one or more embodiments, a high-resolution display panel may be manufactured by a display device process, and the degree of integration of elements may be improved. The scope of the disclosure is not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a first oxide semiconductor layer disposed on the substrate, the first oxide semiconductor layer comprising a channel region, a source region, and a drain region, the source region and the drain region being spaced apart from each other with the channel region therebetween;
a first gate insulating layer continuously disposed on the substrate and covering an upper surface of the first oxide semiconductor layer;
a second oxide semiconductor layer disposed on the first gate insulating layer, the second oxide semiconductor layer comprising a channel region, a source region, and a drain region, the source region and the drain region being spaced apart from each other with the channel region therebetween; and
a second gate insulating layer disposed to cover an upper surface of the second oxide semiconductor layer,
wherein the first gate insulating layer has a first thickness in a direction perpendicular to the substrate,
the second gate insulating layer has a second thickness in a direction perpendicular to the substrate, and
a difference between the first thickness and the second thickness is 500 Å or less.

2. The display device of claim 1, wherein
the first gate insulating layer is disposed to completely cover the upper surface of the first oxide semiconductor layer, and
the second gate insulating layer is disposed to completely cover the upper surface of the second oxide semiconductor layer.

3. The display device of claim 1, wherein the first gate insulating layer and the second gate insulating layer include a same material as each other.

4. The display device of claim 1, wherein the first oxide semiconductor layer and the second oxide semiconductor layer include different materials from each other.

5. The display device of claim 4, wherein
the first oxide semiconductor layer includes indium gallium zinc oxide (IGZO), and
the second oxide semiconductor layer includes indium tin gallium zinc oxide (ITGZO).

6. The display device of claim 4, wherein
the first oxide semiconductor layer includes ITGZO, and
the second oxide semiconductor layer includes IGZO.

7. The display device of claim 1, further comprising a third oxide semiconductor layer disposed on the substrate.

8. The display device of claim 7, wherein the third oxide semiconductor layer includes IGZO and/or ITGZO.

9. The display device of claim 1, wherein the first oxide semiconductor layer or the second oxide semiconductor layer has a structure in which a layer including IGZO and a layer including ITGZO are stacked.

10. The display device of claim 1, wherein the source region and the drain region of the first oxide semiconductor layer and the source region and the drain region of the second oxide semiconductor layer include doped ions.

11. The display device of claim 1, further comprising:
a first gate electrode disposed on the first gate insulating layer and overlapping the channel region of the first oxide semiconductor layer; and
a second gate electrode disposed on the second gate insulating layer and overlapping the channel region of the second oxide semiconductor layer.

12. A method of manufacturing a display device, the method comprising:
forming a first oxide semiconductor layer and a third oxide semiconductor layer on a substrate;
forming a first gate insulating layer on the first oxide semiconductor layer and the third oxide semiconductor layer, the first gate insulating layer being continuously formed on the substrate to completely cover upper surfaces of the first oxide semiconductor layer and the third oxide semiconductor layer;
forming a second oxide semiconductor layer on the first gate insulating layer; and
forming a second gate insulating layer on the second oxide semiconductor layer to completely cover an upper surface of the second oxide semiconductor layer,
wherein the first gate insulating layer has a first thickness in a direction perpendicular to the substrate,
the second gate insulating layer has a second thickness in a direction perpendicular to the substrate, and
a difference between the first thickness and the second thickness is 500 Å or less.

13. The method of claim 12, wherein the forming of the second gate insulating layer on the second oxide semiconductor layer to completely cover the upper surface of the second oxide semiconductor layer comprises:
disposing a second gate insulating layer forming material on the second oxide semiconductor layer;
disposing a photoresist on a portion of the second gate insulating layer forming material overlapping the second oxide semiconductor layer;
forming a second gate insulating layer by etching a portion of the second gate insulating layer forming material on which the photoresist is not disposed; and
removing the photoresist.

14. The method of claim 12, further comprising:
forming, on the first gate insulating layer, a first gate electrode overlapping at least a portion of the first oxide semiconductor layer; and
forming, on the second gate insulating layer, a second gate electrode overlapping at least a portion of the second oxide semiconductor layer.

15. The method of claim 14, further comprising doping ion impurities into a portion of the first oxide semiconductor layer that does not overlap the first gate electrode, a portion of the second oxide semiconductor layer that does not overlap the second gate electrode, and the third oxide semiconductor layer.

16. The method of claim 12, wherein the first oxide semiconductor layer and the second oxide semiconductor layer include different materials from each other.

17. The method of claim 16, wherein
the first oxide semiconductor layer includes indium gallium zinc oxide (IGZO), and
the second oxide semiconductor layer includes indium tin gallium zinc oxide (ITGZO).

18. The method of claim 16, wherein the first oxide semiconductor layer includes ITGZO, and
the second oxide semiconductor layer includes IGZO.

19. The method of claim 12, wherein the first oxide semiconductor layer or the second oxide semiconductor layer has a structure in which a layer including IGZO and a layer including ITGZO are stacked in multiple layers.

20. A display device comprising:
a substrate;
a first oxide semiconductor layer disposed on the substrate, the first oxide semiconductor layer comprising a channel region, a source region, and a drain region, the source region and the drain region being spaced apart from each other with the channel region therebetween;
a first gate insulating layer continuously disposed on the substrate and completely covering an upper surface of the first oxide semiconductor layer;
a second oxide semiconductor layer disposed on the first gate insulating layer, the second oxide semiconductor layer comprising a channel region, a source region, and a drain region, the source region and the drain region being spaced apart from each other with the channel region therebetween; and
a second gate insulating layer continuously disposed on the substrate and completely covering an upper surface of the second oxide semiconductor layer,
wherein the source region and the drain region of the first oxide semiconductor layer and the source region and the drain region of the second oxide semiconductor layer include doped ions.

21. The display device of claim 20, further comprising a third oxide semiconductor layer disposed on the substrate.

22. A method of manufacturing a display device, the method comprising:
forming a first oxide semiconductor layer and a third oxide semiconductor layer on a substrate;
forming a first gate insulating layer on the first oxide semiconductor layer and the third oxide semiconductor layer, the first gate insulating layer being continuously formed on the substrate to completely cover upper surfaces of the first oxide semiconductor layer and the third oxide semiconductor layer;
forming a second oxide semiconductor layer on the first gate insulating layer; and
forming a second gate insulating layer on the second oxide semiconductor layer, the second gate insulating layer being continuously formed on the substrate to completely cover an upper surface of the second oxide semiconductor layer,
wherein at least a portion of the first oxide semiconductor layer and at least a portion of the second oxide semiconductor layer include doped ions.

23. The method of claim 22, further comprising, after the forming of the first gate insulating layer on the first oxide semiconductor layer and the third oxide semiconductor layer:
forming, on the first gate insulating layer, a first photoresist that is patterned to overlap at least a portion of the first oxide semiconductor layer;
doping ions into the third oxide semiconductor layer and a portion of the first oxide semiconductor layer that does not overlap the photoresist; and
removing the first photoresist.

24. The method of claim 22, further comprising, after the forming of the second gate insulating layer on the second oxide semiconductor layer:
forming a second photoresist that is patterned to overlap all of the first oxide semiconductor layer, all of the third oxide semiconductor layer, and a portion of the second oxide semiconductor layer;
doping ions into a portion of the second oxide semiconductor layer that does not overlap the second photoresist; and
removing the second photoresist.
